(19) United States
(12) Patent Application Publication
(10) Pub. No.: US 2026/0082591 A1
(43) Pub. Date: Mar. 19, 2026

(54) SEMICONDUCTOR STORAGE DEVICE

(71) Applicant: Kioxia Corporation, Tokyo (JP)

(72) Inventors: Tomonori INOUE, Yokohama Kanagawa (JP); Yoshitaka KUBOTA, Sagamihara Kanagawa (JP)

(21) Appl. No.: 19/073,711

(22) Filed: Mar. 7, 2025

(30) Foreign Application Priority Data
Sep. 18, 2024 (JP) 2024-161170

(51) Int. Cl. H10B 80/00; H01L 23/00; H01L 25/00; H01L 25/065; H01L 25/18

(52) U.S. Cl. CPC H10B 80/00; H10W 90/00; H10W 72/9445; H10W 72/963; H10W 72/967; H10W 80/312; H10W 80/327; H10W 90/792

(57) ABSTRACT

A semiconductor storage device includes first and second chips. The second chip has a memory region and an edge seal region, and includes a plurality of edge seals, a first wiring layer at a first layer level on a first chip side of the edge seals, and a second wiring layer at a second layer level and contains tungsten. The first wiring layer includes first wirings at positions overlapping with inner edge seals, respectively, but not with an outermost edge seal and electrically connected to the inner edge seals, respectively. The second wiring layer includes second wirings that are provided at positions overlapping with the inner edge seals, respectively, but not with the outermost edge seal, and electrically connected to the inner edge seals, respectively, and a third wiring provided on an outer side of the second wirings, and electrically separated and spaced apart from the outermost edge seal.

### CROSS-REFERENCE TO RELATED APPLICATIONS

This application is based upon and claims the benefit of priority from Japanese Patent Application No. 2024-161170, filed Sep. 18, 2024, the entire contents of which are incorporated herein by reference.

### FIELD

Embodiments described hereunder relate generally to a semiconductor storage device.

### BACKGROUND

A semiconductor storage device of one type includes a substrate, a plurality of conductive layers stacked in a direction intersecting the surface of the substrate, a semiconductor layer facing the plurality of conductive layers, and a gate insulating layer provided between the conductive layers and the semiconductor layer. The gate insulating layer includes a memory unit capable of storing data, such as an insulating charge storage layer made of a material such as silicon nitride (SiN) or a conductive charge storage layer such as a floating gate.

### BRIEF DESCRIPTION OF THE DRAWINGS

FIG. 1 is a exploded perspective view diagram schematically showing a configuration example of a semiconductor storage device according to a first embodiment.

FIG. 2 is a bottom view diagram schematically showing a configuration example of a chip C_{M}.

FIG. 3 is a bottom view diagram schematically showing a configuration example of the chip C_{M}.

FIG. 4 is a bottom view diagram schematically showing an enlarged part of FIG. 2.

FIG. 5 is a plan view diagram schematically showing a configuration example of a chip C_{P}.

FIG. 6 is a plan view diagram schematically showing an enlarged part of FIG. 5.

FIG. 7 is a cross sectional diagram schematically showing a configuration of a part of a memory die MD.

FIG. 8 is a cross sectional diagram schematically showing an enlarged part of FIG. 7.

FIG. 9 is a cross sectional diagram schematically showing an enlarged part of FIG. 8.

FIG. 10 is a cross sectional diagram schematically showing a configuration example of an edge seal region and a kerf region according to the first embodiment.

FIG. 11 is a bottom view diagram for describing a method for manufacturing a semiconductor storage device according to the first embodiment.

FIGS. 12-30 are cross sectional diagrams for describing the same manufacturing method.

FIG. 31 is a plan view diagram schematically showing the arrangement of a plurality of edge seals in an edge seal region and the arrangement of wiring layers M1 in Example 1 of the first embodiment.

FIG. 32 is a plan view diagram schematically showing an enlarged part of FIG. 31.

FIG. 33 is a cross sectional diagram schematically showing the structure of the wiring layer M1 provided below an edge seal ES6 when taken along a dotted line E-E′ in FIG. 31.

FIG. 34 is a plan view diagram schematically showing the arrangement of a plurality of edge seals in an edge seal region and the arrangement of wiring layers M1 in Example 2 of the first embodiment.

FIG. 35 is a plan view diagram schematically showing an enlarged part of FIG. 34.

FIG. 36 is a cross sectional diagram schematically showing the structure of the wiring layers M1 provided below the edge seal ES6 when taken along a dotted line F-F′ in FIG. 34.

FIG. 37 is a plan view diagram schematically showing the arrangement of a plurality of edge seals in an edge seal region and the arrangement of wiring layers M1 in Example 3 of the first embodiment.

FIG. 38 is a plan view diagram schematically showing an enlarged par of FIG. 37.

FIG. 39 is a cross sectional diagram schematically showing the structure of a wiring layer M1 provided below the edge seal ES6 when taken along a dotted line G-G′ in FIG. 37.

FIG. 40 is a plan view diagram schematically showing the arrangement of a plurality of edge seals in an edge seal region and the arrangement of a wiring layer M1 in Example 4 of the first embodiment.

FIG. 41 is a plan view diagram schematically showing an enlarged part of FIG. 40.

FIG. 42 is a cross sectional diagram schematically showing the structure of the wiring layer M1 provided below the edge seal ES6 when taken along a dotted line H-H′ in FIG. 40.

FIG. 43 is a plan view diagram schematically showing the arrangement of a plurality of edge seals in an edge seal region and the arrangement of wiring layers M1 in Example 5 of the first embodiment.

FIG. 44 is a plan view diagram schematically showing an enlarged part of FIG. 43.

FIG. 45 is a cross sectional diagram schematically showing the structures of an edge seal ES6 and a conductive layer below the edge seal ES6 according to another embodiment.

FIG. 46 is a cross sectional diagram schematically showing the structure of an edge seal ES6 and a conductive layer below the edge seal ES6 according to another embodiment.

FIG. 47 is a cross sectional diagram schematically showing the structure of an edge seal ES6 and a conductive layer below the edge seal ES6 according to another embodiment.

FIG. 48 is a cross sectional diagram schematically showing the structure of an edge seal ES6 and a conductive layer below the edge seal ES6 according to another embodiment.

FIG. 49 is a plan view diagram schematically showing the arrangement of a plurality of edge seals in an edge seal region and the arrangement of wiring layers M0 and M1 according to another embodiment.

FIG. 50 is a cross sectional diagram schematically showing the structure of the wiring layers M and M1 provided below the edge seal ES6 when taken along a dotted line I-I′ in FIG. 49.

### DETAILED DESCRIPTION

A semiconductor storage device that can be suitably manufactured is provided.

In general, according to an embodiment, a semiconductor storage device includes a first chip and a second chip bonded together via a plurality of bonding electrodes. The second chip has a memory region including a memory cell array and an edge seal region surrounding the memory region. The first chip includes a semiconductor substrate. The second chip includes a plurality of edge seals, a first wiring layer provided at a first layer level on a first chip side of the plurality of edge seals, and a second wiring layer that is provided at a second layer level on a first chip side of the first wiring layer and contains tungsten (W). Each edge seal extends in the edge seal region in a first direction intersecting a surface of the semiconductor substrate and surrounds the memory region as viewed in the first direction. The plurality of edge seals includes two or more inner edge seals and an outermost edge seal that is an outermost one of the plurality of edge seals. The first wiring layer includes a plurality of first wirings that are provided in the edge seal region at positions overlapping with the inner edge seals, respectively, but not with the outermost edge seal, as viewed in the first direction and electrically connected to the inner edge seals, respectively. The second wiring layer includes a plurality of second wirings that are provided in the edge seal region at positions overlapping with the inner edge seals, respectively, but not with the outermost edge seal, as viewed in the first direction and electrically connected to the inner edge seals, respectively, and a third wiring that is provided in the edge seal region on an outer side of the second wirings as viewed in the first direction, and electrically separated and spaced apart from the outermost edge seal.

Next, semiconductor storage devices according to embodiments will be described in detail with reference to the drawings. It is noted that the following embodiments are merely examples, and are not intended to limit the present invention. Furthermore, the following drawings are schematic, and some configurations may be omitted for the sake of explanation. In addition, portions common to a plurality of embodiments may be given the same reference signs, and descriptions thereon may be omitted.

Furthermore, when the term “semiconductor storage device” is used in the present disclosure, it may mean a memory die after dicing, or a wafer before dicing. In the former case, it may mean a memory die after packaged, or a memory die before packaged. Furthermore, in the latter case, it may mean a wafer before bonding, or a wafer after bonding.

Furthermore, in the present disclosure, when it is described that a first configuration is “electrically connected to” a second configuration, the first configuration may be directly connected to the second configuration, or the first configuration may be connected to the second configuration via wiring, a semiconductor member, a transistor, or the like. For example, when three transistors are connected in series, the first transistor is “electrically connected” to the third transistor even when the second transistor is in an OFF state.

Furthermore, in the present disclosure, when it is described that a first configuration is “connected between” a second configuration and a third configuration, it may mean that the first configuration, the second configuration, and the third configuration are connected in series, and the second configuration is connected to the third configuration via the first configuration.

Furthermore, in the present disclosure, when it is described that a circuit or the like “conducts” two wirings or the like, it may mean, for example, that this circuit or the like includes a transistor or the like, that this transistor or the like is provided in a current path between the two wirings, and this transistor or the like is in an ON state.

Furthermore, in the present disclosure, a specific direction parallel to the surface of a substrate is referred to as an X-direction, a direction that is parallel to the surface of the substrate and perpendicular to the X-direction is referred to as a Y-direction, and a direction perpendicular to the surface of the substrate is referred to as a Z-direction.

Furthermore, in the present disclosure, a direction along a specific surface may be referred to as a first direction, a direction that is along this specific surface and intersects the first direction may be referred to as a second direction, and a direction that intersects this specific surface may be referred to as a third direction. These first, second, and third directions may or may not correspond to any of the X, Y, and Z-directions.

Furthermore, when expressions such as “upper” and “lower” are used in the present disclosure, for example, with respect to two chips or two wafers included in a memory die, wafer, or the like, one chip or wafer that is provided with an external pad electrode connectable to a bonding wire may be referred to as an upper chip or wafer, and the other chip or wafer that is not provided with such an external pad electrode may be referred to as a lower chip or wafer. Furthermore, when a configuration included in a memory die, wafer, or the like is referred to, for example, a direction that leaves a semiconductor substrate included in the lower wafer along the Z-direction may be referred to as “up”, and a direction that approaches to the semiconductor substrate included in the lower wafer along the Z-direction may be referred to as “down”. Furthermore, when a lower surface or a lower end is referred to for a certain configuration, it may mean a surface or an end portion on the semiconductor substrate side included in the lower wafer of this configuration, and when an upper surface or an upper end is referred to for a certain configuration, it may mean a surface or an end portion on the opposite side to the semiconductor substrate included in the lower wafer of this configuration. Furthermore, a surface that intersects the X-direction or Y-direction may be referred to as a side surface or the like.

Furthermore, in the present disclosure, when “width,” “length,”, “thickness” or the like in a predetermined direction is referred to for a configuration, a member, etc., it may mean the width, length, thickness or the like in a section or the like observed by scanning electron microscopy (SEM), transmission electron microscopy (TEM) or the like.

### First Embodiment

### Structure of Memory Die MD

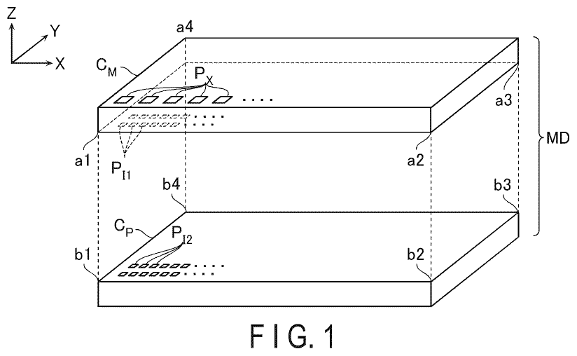

FIG. 1 is an exploded perspective view diagram schematically showing a configuration example of a semiconductor storage device according to a first present embodiment. As shown in FIG. 1, the memory die MD includes a chip C_{M} on a memory cell array side, and a chip C_{P} on a peripheral circuit side.

The upper surface of the chip C_{M} is provided with a plurality of external pad electrodes P_{X} that can be connected to bonding wires (not shown). The lower surface of the chip C_{M} is provided with a plurality of bonding electrodes P_{I1}. Furthermore, the upper surface of the chip C_{P} is provided with a plurality of bonding electrodes P_{I2}. Hereinafter, with respect to the chip C_{M}, a surface of the chip C_{M} on which the plurality of bonding electrodes P_{I1} are provided is referred to as a front surface, and a surface of the chip C_{M} on which the plurality of external pad electrodes P_{X} are provided is referred to as a back surface. With respect to the chip C_{P}, a surface of the chip C_{P} on which the plurality of bonding electrodes P_{I2} are provided is referred to as a front surface, and a surface of the chip C_{P} which is opposite to the front surface of the chip C_{P} is referred to as a back surface. In the illustrated example, the front surface of the chip C_{P} is provided above the back surface of the chip C_{P}, and the back surface of the chip C_{M} is provided above the front surface of the chip C_{M}.

The chip C_{M} and the chip C_{P} are arranged such that the front surface of the chip C_{M} faces the front surface of the chip C_{P}. The plurality of bonding electrodes P_{I1} are provided to correspond to the plurality of bonding electrodes P_{I2} respectively, and are arranged at positions where they can be bonded to the plurality of bonding electrodes P_{I2}. The bonding electrodes P_{I1} and P_{I2} function as bonding electrodes for bonding the chip C_{M} and the chip C_{P} and electrically conducting them together.

In the example of FIG. 1, corner portions a1, a2, a3, and a4 of the chip C_{M} correspond to corner portions b1, b2, b3, and b4 of the chip C_{P}, respectively.

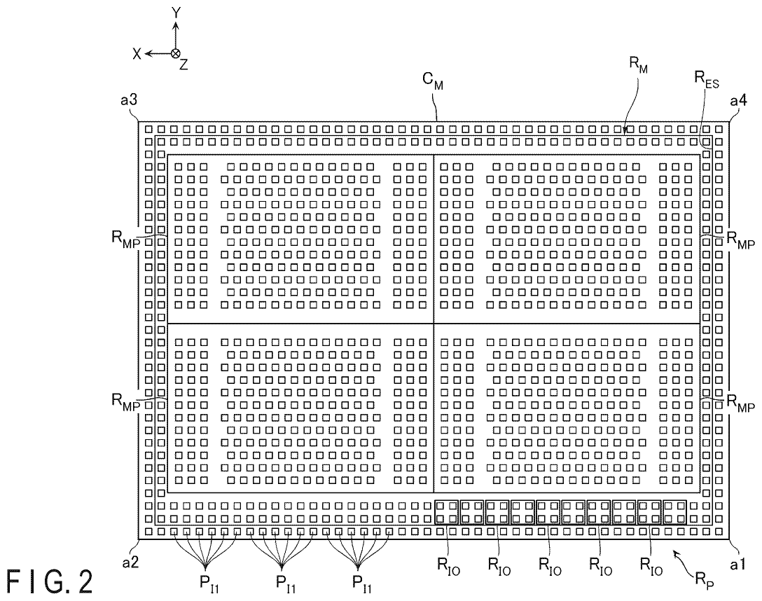

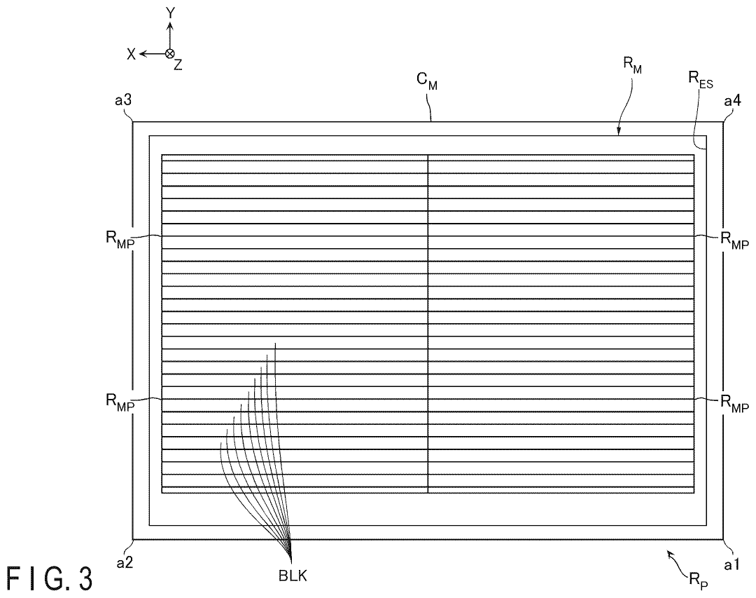

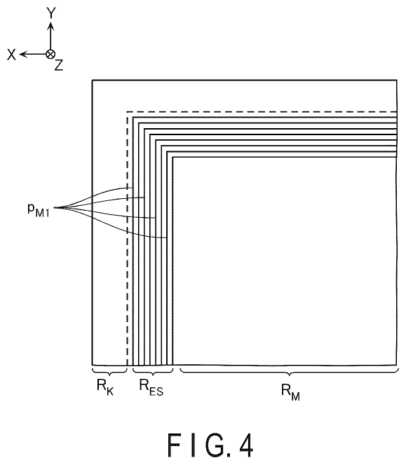

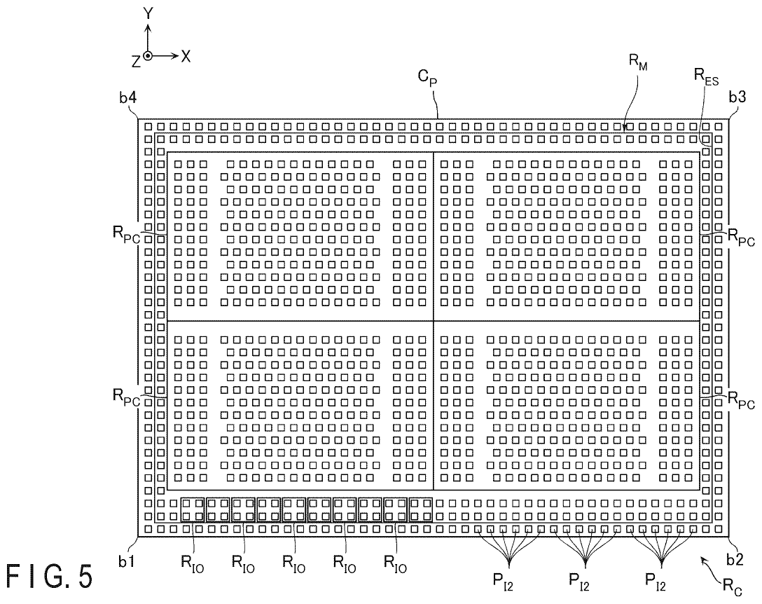

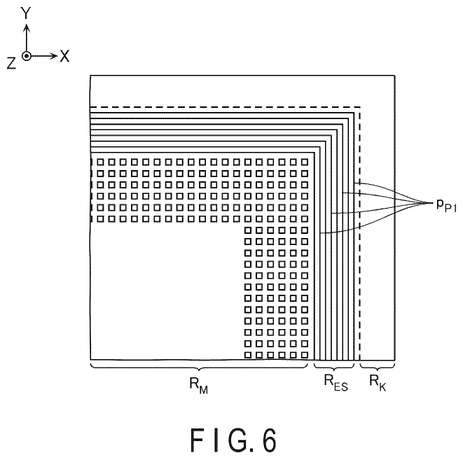

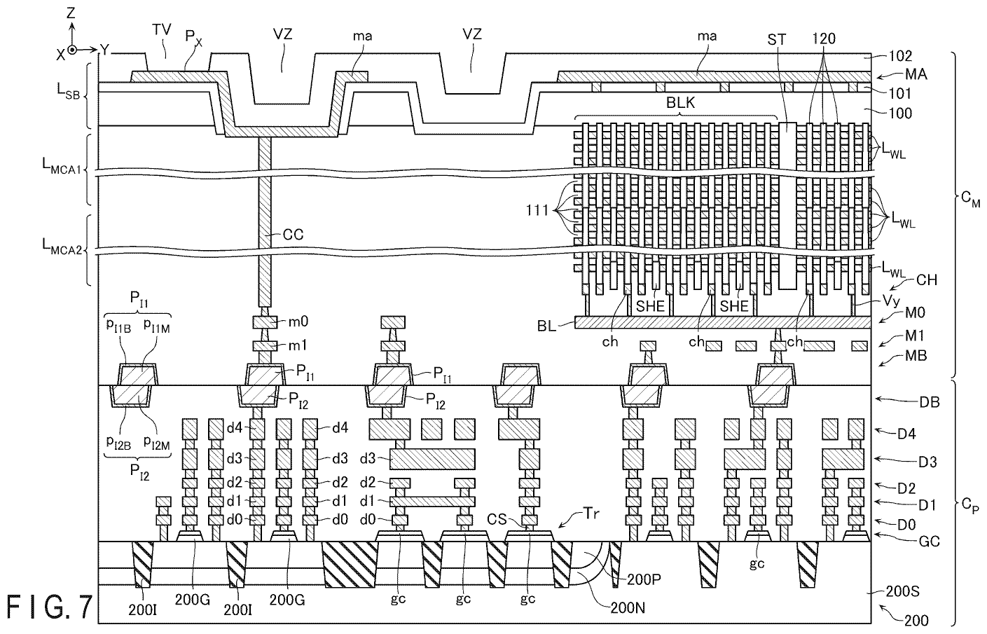

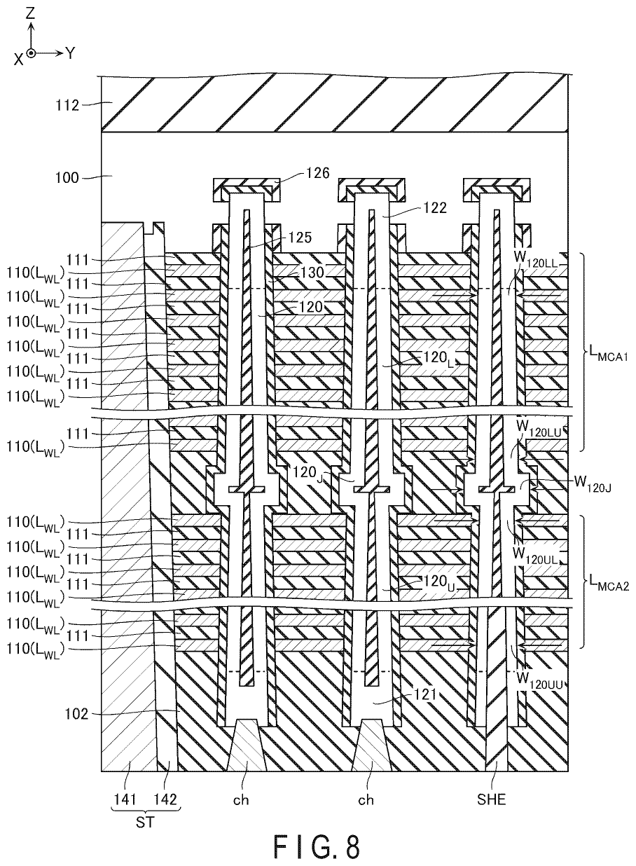

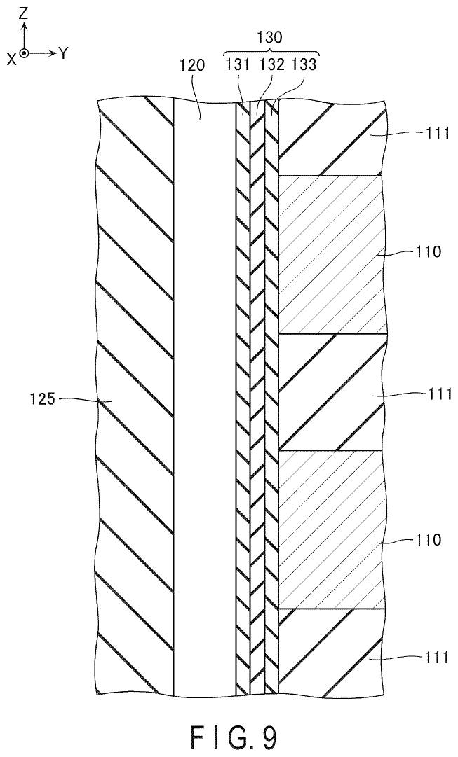

FIGS. 2 and 3 are bottom view diagrams schematically showing a configuration example of the chip C_{M}. In FIG. 3, some configurations of the bonding electrodes P_{I1}, etc. are omitted. FIG. 4 is a bottom view diagram schematically showing an enlarged part of FIG. 2. FIG. 5 is a plan view diagram schematically showing a configuration example of the chip C_{P}. FIG. 6 is a plan view diagram schematically showing an enlarged part of FIG. 5. FIG. 7 is a cross sectional diagram schematically showing a partial configuration of the memory die MD. FIG. 8 is a cross sectional diagram schematically showing an enlarged part of FIG. 7. FIG. 9 is a cross sectional diagram schematically showing an enlarged part of FIG. 8. It is noted that FIG. 9 shows a YZ-section, but a structure similar to that of FIG. 9 is observed when a section (for example, an XZ-section) other than the YZ-section along the central axis of the semiconductor layer 120 is observed.

### Structure of Chip C_{M}

For example, as shown in FIG. 2, the chip C_{M} has four memory plane regions R_{MP} arranged side by side in the X-direction and the Y-direction. The chip C_{M} also has a peripheral region RP provided to be closer to one end side in the Y-direction than the four memory plane regions R_{MP}. The peripheral region R_{P} has a plurality of input/output regions R_{IO} arranged side by side in the X-direction. The chip C_{M} also has an edge seal region R_{ES} surrounding these four memory plane regions R_{MP} and the plurality of input/output regions R_{IO}. As shown in FIG. 4, a kerf region R_{K} is provided outside the edge seal region R_{ES}. It is noted that the kerf region R_{K} may remain partially even after dicing or may not remain at all. In the following description, a region inside the edge seal region R_{ES} (the region including the four memory plane regions R_{MP} and the peripheral region R_{P}) may be referred to as a memory region R_{M}.

For example, as shown in FIG. 7, the chip C_{M} includes a base structure L_{SB}, memory cell array layers L_{MCA1} and L_{MCA2} provided below the base structure L_{SB}, and a plurality of wiring layers CH, M0, M1, and MB provided below the memory cell array layers L_{MCA1} and L_{MCA2}. The memory cell array layers L_{MCA1} and L_{MCA2} each include a plurality of word-line layers L_{WL} arranged in the Z-direction. An insulating layer 111 such as silicon oxide (SiO₂) is provided between the plurality of word-line layers L_{WL} arranged side by side in the Z-direction.

### Structure of Base Structure L_{SB} of Chip C_{M}

For example, as shown in FIG. 7, the base structure L_{SB} includes a conductive layer 100 provided on the upper surface of the memory cell array layer L_{MCA1}, an insulating layer 101 provided on the upper surface of the conductive layer 100, a back surface wiring layer MA provided on the upper surface of the insulating layer 101, and an insulating layer 102 provided on the upper surface of the back surface wiring layer MA.

The conductive layer 100 may include a semiconductor layer of silicon (Si) or the like which is doped with N-type impurities such as phosphorus (P) or P-type impurities such as boron (B), or may contain metal such as tungsten (W), or may contain silicide such as tungsten silicide (WSi).

The conductive layer 100 functions as a part of a source line of an NAND flash memory. Four conductive layers 100 are provided so as to correspond to the four memory plane regions R_{MP} (FIG. 2) arranged side by side in the X-direction and the Y-direction. Regions VZ that do not include conductive layers 100 are provided at the end portions of the memory plane regions R_{MP} in the X-direction and the Y-direction.

The insulating layer 101 contains, for example, silicon oxide (SiO₂).

The back surface wiring layer MA includes a plurality of wirings ma. These wirings ma may contain, for example, aluminum (Al).

Some of the wirings ma function as some of the source lines of the NAND flash memory. Four wirings ma are provided so as to correspond to the four memory plane regions R_{MP} (FIG. 2) arranged side by side in the X-direction and the Y-direction. Each of these wirings ma is electrically connected to the conductive layer 100.

Some of the wirings ma function as external pad electrodes P_{X}. A plurality of these wirings ma are provided so as to correspond to the plurality of input/output regions R_{IO} (FIG. 2) arranged side by side in the X-direction. The wirings ma are connected to a via contact electrode CC in the memory cell array layers L_{MCA1} and L_{MCA2} in a region VZ that does not include the conductive layer 100. Some of the wirings ma are exposed to the outside of the memory die MD through an opening TV provided in the insulating layer 102.

The insulating layer 102 is a passivation layer that contains a resin material such as polyimide in an upper layer portion thereof.

### Structure of Memory Plane Region R_{MP} of Memory Cell Array Layers L_{MCA1}, L_{MCA2} of Chip C_{M}

For example, as shown in FIG. 3, the memory cell array layers L_{MCA1}, L_{MCA2} are provided with a plurality of memory blocks BLK arranged side by side in the Y-direction. As shown in FIG. 7, an inter-block structure ST is provided between two memory blocks BLK adjacent to each other in the Y-direction.

For example, as shown in FIG. 8, the memory block BLK includes a plurality of conductive layers 110 arranged side by side in the Z-direction so as to correspond to the plurality of word-line layers L_{WL}, a plurality of semiconductor layers 120 extending in the Z-direction, and a plurality of gate insulating films 130 provided between the plurality of conductive layers 110 and the plurality of semiconductor layers 120.

The conductive layer 110 has a substantially plate-like shape extending in the X-direction. The conductive layer 110 may include stacked films or the like of a barrier conductive film of titanium nitride (TiN) or the like and a metal film of tungsten (W) or the like. Furthermore, the conductive layer 110 may also include polycrystalline silicon or the like which contains impurities such as phosphorus (P) or boron (B).

Among the plurality of conductive layers 110, one or more conductive layers 110 located in the uppermost layer function as a select gate line of the NAND flash memory and gate electrodes of a plurality of select transistors connected thereto. The plurality of conductive layers 110 are electrically independent for each memory block BLK.

The plurality of conductive layers 110 located below the one or more conductive layers 110 described above function as word-lines of the NAND flash memory and gate electrodes of a plurality of memory cells (memory transistors) connected thereto. Each of these conductive layers 110 is electrically independent for each memory block BLK.

Furthermore, one or more conductive layers 110 located below the plurality of conductive layers 110 described above function as a select gate line of the NAND flash memory and gate electrodes of a plurality of select transistors connected thereto. These conductive layers 110 have a smaller width in the Y-direction than the other conductive layers 110. Furthermore, an insulating layer SHE of silicon oxide (SiO₂) or the like is provided between two conductive layers 110 adjacent to each other in the Y-direction.

The semiconductor layers 120 are arranged in a predetermined pattern in the X-direction and the Y-direction. The semiconductor layers 120 function as the memory cells of the NAND flash memory and the channel regions of the select transistors. The semiconductor layer 120 contains, for example, polycrystalline silicon (Si). The semiconductor layer 120 has a substantially cylindrical shape, and an insulating layer 125 of silicon oxide or the like is provided in the center.

The semiconductor layer 120 has a semiconductor region 120_{L} included in the memory cell array layer L_{MCA1} and a semiconductor region 120_{U} included in the memory cell array layer L_{MCA2}. Furthermore, the semiconductor layer 120 also includes a semiconductor region 120_{J} connected to the lower end of the semiconductor region 120_{L} and the upper end of the semiconductor region 120_{U}, an impurity region 122 connected to the upper end of the semiconductor region 120_{L}, and an impurity region 121 connected to the lower end of the semiconductor region 120_{U}.

The semiconductor region 120_{L} has a substantially cylindrical shape extending in the Z-direction. The outer peripheral surface of each semiconductor region 120_{L} is surrounded by a plurality of conductive layers 110 included in the memory cell array layer L_{MCA1}, and faces these conductive layers 110. The width W_{120LL} in the radial direction of the upper end portion of the semiconductor region 120_{L} is smaller than the width W_{120LU} in the radial direction of the lower end portion of the semiconductor region 120_{L}.

The semiconductor region 120_{U} has a substantially cylindrical shape extending in the Z-direction. The outer peripheral surface of each semiconductor region 120_{U} is surrounded by the plurality of conductive layers 110 included in the memory cell array layer L_{MCA2}, and faces these conductive layers 110. It is noted that the width W_{120UL} in the radial direction of the upper end portion of the semiconductor region 120_{U} is smaller than the width W_{120UU} in the radial direction of the lower end portion of the semiconductor region 120_{U} and the above-mentioned width W_{120LU}.

Each semiconductor region 120_{J} is provided below the plurality of conductive layers 110 included in the memory cell array layer L_{MCA1}, and also provided above the plurality of conductive layers 110 included in the memory cell array layer L_{MCA2}. It is noted that the width W_{120J} in the radial direction of the semiconductor region 120_{J} is larger than the above-Mentioned widths W_{120LU} and W_{120UU}.

The impurity region 122 is connected to the conductive layer 100. In the example of FIG. 8, the boundary between the semiconductor region 120_{L} and the impurity region 122 is indicated by a dashed line. The impurity region 122 contains, for example, an N-type impurity such as phosphorus (P) or a P-type impurity such as boron (B).

The impurity region 121 contains, for example, an N-type impurity such as phosphorus (P). In the example of FIG. 8, the boundary between the semiconductor region 120_{U} and the impurity region 121 is indicated by a dashed line. The impurity regions 121 are connected to the bit-line BL via wirings ch and wirings Vy (FIG. 7).

The gate insulating film 130 has a substantially cylindrical shape covering the outer peripheral surface of the semiconductor layer 120. For example, as shown in FIG. 9, the gate insulating film 130 includes a tunnel insulating film 131, a charge storage film 132, and a block insulating film 133 which are stacked between the semiconductor layer 120 and the conductive layer 110. The tunnel insulating film 131 and the block insulating film 133 contain, for example, silicon oxide (SiO₂) or the like. The charge storage film 132 includes, for example, a film capable of holding charges such as a silicon nitride (SiN). The tunnel insulating film 131, the charge storage film 132, and the block insulating film 133 have a substantially cylindrical shape, and extend in the Z-direction along the outer peripheral surface of the semiconductor layer 120 except for the contact portion between the semiconductor layer 120 and the conductive layer 100. Furthermore, as shown in FIG. 8, an insulating layer 126 of silicon oxide (SiO₂) or the like is provided between the gate insulating film 130 and the conductive layer 100.

FIG. 9 shows an example in which the gate insulating film 130 includes the charge storage film 132 of silicon nitride or the like. However, the gate insulating film 130 may include a floating gate of polycrystalline silicon containing N-type or P-type impurities, or the like.

For example, as shown in FIG. 8, the inter-block structure ST includes a conductive layer 141 extending in the Z-direction and the X-direction, and an insulating layer 142 provided on the side surface of the conductive layer 141. The conductive layer 141 is connected to the conductive layer 100. The conductive layer 141 may include stacked films or the like of a barrier conductive film of titanium nitride (TiN) or the like and a metal film of tungsten (W) or the like. The conductive layer 141 functions, for example, as a part of the source line of the NAND flash memory.

### Structure of Peripheral Region R_{P} of Memory Cell Array Layers L_{MCA1}, L_{MCA2} of Chip C_{M}

For example, as shown in FIG. 7, the peripheral region R_{P} is provided with a plurality of via contact electrodes CC so as to correspond to external pad electrodes P_{X}. The upper ends of the plurality of via contact electrodes CC are connected to wirings ma functioning as the external pad electrodes P_{X}.

### Structure of Wiring Layers CH, M0, M1, MB of Chip C_{M}

For example, as shown in FIG. 7, a plurality of wirings included in the wiring layers CH, M0, M1, MB are electrically connected to at least one of the configurations of the memory cell array layers L_{MCA1}, L_{MCA2} and the configuration in the chip C_{P}.

The wiring layer CH includes a plurality of wirings ch as the plurality of wirings. These wirings ch may include, for example, stacked films of a barrier conductive film of titanium nitride (TiN) or the like and a metal film of tungsten (W) or the like. The wirings ch are provided so as to correspond to the plurality of semiconductor layers 120 and are connected to the lower ends of the plurality of semiconductor layers 120.

The wiring layer M0 includes a plurality of wirings m0. These wirings m0 may include, for example, a stack film of a barrier conductive film of titanium nitride (TiN) or the like and a metal film of copper (Cu) or the like. Some of the wirings m0 function as bit-lines BL. The bit-lines BL are arranged side by side in the X-direction and extend in the Y-direction, for example.

For example, as shown in FIG. 7, the wiring layer M1 includes a plurality of wirings m1. These wirings m1 may include, for example, stacked films or the like of a barrier conductive film of titanium nitride (TiN) or the like and a metal film of tungsten (W) or the like.

The wiring layer MB includes a plurality of bonding electrodes P_{I1}. These bonding electrodes P_{I1} may include, for example, stacked films or the like of a barrier conductive film p_{I1B} of titanium nitride (TiN) or the like and a metal film p_{I1M} of copper (Cu) or the like.

As shown in FIG. 4, in the edge seal region R_{ES}, a line-and-space pattern p_{M1} extending along the four sides of the memory die MD may be formed in the wiring layers CH, M0, and M1. Furthermore, at least a part of the line-and-space pattern p_{M1} may be formed in the wiring layer MB.

### Structure of Chip C_{P}

For example, as shown in FIG. 5, the chip C_{P} has four peripheral circuit regions R_{PC} arranged side by side in the X-direction and the Y-direction so as to correspond to the memory plane region R_{MP}. The chip C_{P} also has a circuit region R_{C} provided in a region facing the peripheral region R_{P}. The circuit region R_{C} has a plurality of input/output regions R_{IO} arranged side by side in the X-direction. The chip C_{P} is also provided with an edge seal region R_{ES} surrounding the four peripheral circuit regions R_{PC} and the input/output region R_{IO}. As shown in FIG. 6, a kerf region R_{K} is provided outside the edge seal region R_{ES}. It is noted that, in the chip C_{P}, the kerf region RK may remain partially even after dicing, but may not remain at all as in the case of the chip C_{M}. In the following description, in the chip C_{P} as in the chip C_{M}, the region inside the edge seal region R_{ES} (the region including the four peripheral circuit regions R_{PC} and the circuit region R_{C}) may be referred to as a memory region R_{M}.

For example, as shown in FIG. 7, the chip C_{P} also includes a semiconductor substrate 200, an electrode layer GC provided above the semiconductor substrate 200, and wiring layers D0, D1, D2, D3, D4, and DB provided above the electrode layer GC.

### Structure of Semiconductor Substrate 200 of Chip C_{P}

The semiconductor substrate 200 contains, for example, P-type silicon (Si) containing P-type impurities such as boron (B). On the surface of the semiconductor substrate 200 are provided, for example, an N-type well region 200N containing N-type impurities such as phosphorus (P), a P-type well region 200P containing P-type impurities such as boron (B), a semiconductor substrate region 200S in which neither the N-type well region 200N nor the P-type well region 200P is provided, and an insulating region 200I. The N-type well region 200N, the P-type well region 200P, and the semiconductor substrate region 200S each function as parts of a plurality of transistors Tr and a plurality of capacitors that constitute a peripheral circuit.

As shown in FIG. 6, in the edge seal region R_{ES}, a line-and-space pattern p_{P1} extending along the four sides of the memory die MD may be formed on the surface of the semiconductor substrate 200 by the semiconductor substrate region 200S and the insulating region 200I.

### Structure of Electrode Layer GC of Chip CP

For example, as shown in FIG. 7, an electrode layer GC is provided on the upper surface of the semiconductor substrate 200 via an insulating layer 200G. The electrode layer GC includes a plurality of electrodes gc that face the surface of the semiconductor substrate 200 in the Z-direction. Furthermore, each region of the semiconductor substrate 200 and each of the plurality of electrodes gc included in the electrode layer GC are connected to via contact electrodes CS.

The N-type well region 200N, the P-type well region 200P, and the semiconductor substrate region 200S of the semiconductor substrate 200 function as channel regions of the plurality of transistors Tr, one electrodes of the plurality of capacitors, etc. that constitute the peripheral circuit.

The plurality of electrodes gc included in the electrode layer GC function as gate electrodes of the plurality of transistors Tr, the other electrodes of the plurality of capacitors, etc. that constitute the peripheral circuit.

The via contact electrode CS extends in the Z-direction, and is connected at its lower end to the upper surface of the semiconductor substrate 200 or the electrode gc. An impurity region containing N-type impurities or P-type impurities is provided at the connection portion between the via contact electrode CS and the semiconductor substrate 200. The via contact electrode CS may include, for example, stacked films or the like of a barrier conductive film of titanium nitride (TiN) or the like and a metal film of tungsten (W) or the like.

The pattern p_{P1} described with reference to FIG. 6 may be formed on the electrode layer GC.

### Structure of Wiring Layers D0, D1, D2, D3, D4, DB of Chip C_{P}

For example, as shown in FIG. 7, the plurality of wirings included in D0, D1, D2, D3, D4, DB are electrically connected to at least one of the configurations of the memory cell array layers L_{MCA1}, L_{MCA2} and the configuration in the chip C_{P}.

The wiring layers D0, D1, D2 include ma plurality of wirings d0, d1, d2, respectively. These wirings d0, d1, d2 may include, for example, stacked films of a barrier conductive film of titanium nitride (TiN) or the like and a metal film of tungsten (W) or the like.

The wiring layers D3, D4 include a plurality of wirings d3, d4, respectively. These wirings d3, d4 may include, for example, stacked films or the like of a barrier conductive film of titanium nitride (TiN) or the like and a metal film of copper (Cu) or the like.

The wiring layer DB includes a plurality of bonding electrodes P_{I2}. These bonding electrodes P_{I2} may include, for example, stacked films or the like of a barrier conductive film p_{I2B} of titanium nitride (TiN) or the like and a metal film p_{I2M} of copper (Cu) or the like.

Here, when metal films p_{I1M} and p_{I2M} of copper (Cu) or the like are used for the bonding electrodes P_{I1} and P_{I2}, the metal films p_{I1M} and p_{I2M} are integrated with each other, which makes it difficult to observe the boundary therebetween. However, it is possible to observe the bonded structure based on the distortion of the shape of the bonded bonding electrodes P_{I1} and P_{I2} and the misalignment of the barrier conductive films p_{I1B} and p_{I2B} (occurrence of discontinuous portions on the side surfaces) which are caused by misalignment in bonding. Furthermore, when the bonding electrodes P_{I1} and P_{I2} are formed by a damascene process, each side surface has a tapered shape. Therefore, the cross-sectional shape along the Z-direction at the bonded portion between the bonding electrodes P_{I1} and P_{I2} is a non-rectangular shape because the side wall thereof is not linear. Furthermore, when the bonding electrodes P_{I1} and P_{I2} are bonded to each other, the bonded structure of the bonding electrodes P_{I1} and P_{I2} is formed such that the bottom surfaces, side surfaces, and top surfaces of Cu which form the bonded structure are covered with a barrier metal. In contrast, in a wiring layer that uses general Cu, an insulating layer (SiN, SiCN, or the like) having an antioxidation function for Cu is provided on the top surfaces of Cu, and no barrier metal is provided. Therefore, even when no misalignment in bonding occurs, it is possible to distinguish from a general wiring layer.

The pattern p_{P1} described with reference to FIG. 6 may be also formed in the wiring layers D0, D1, D2, D3, and D4. Also, at least a part of the pattern p_{P1} described with reference to FIG. 6 may be formed in the wiring layer DB.

### Structure of Edge Seal Region R_{ES}, etc.

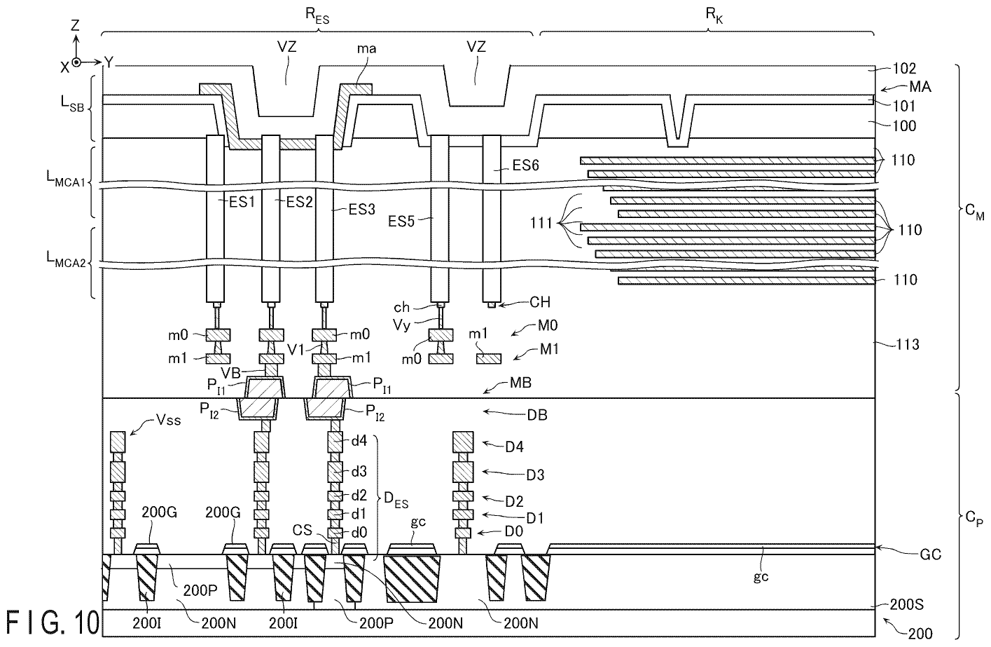

FIG. 10 is a cross sectional diagram schematically showing a configuration example of the edge seal region R_{ES} and the kerf region R_{K} according to the first embodiment.

The memory cell array layers L_{MCA1} and L_{MCA2} in the edge seal region R_{ES} are provided with a plurality of edge seals ES1 to ES6.

The edge seals ES1 to ES6 extend along the Z-direction, and are provided in a ring shape in a region outside the memory region R_{M} on the X-Y plane as viewed in the Z-direction, and arranged to be spaced apart from each other from the inner peripheral side to the outer peripheral side of the edge seal region R_{ES}. The edge seals ES1 to ES6 are configured to be formed at the same time as the inter-block structure ST described with reference to FIG. 8, and include a conductive layer of tungsten or the like and an insulating layer provided on the side surface of the conductive layer like the inter-block structure ST. The edge seals ES1 to ES6 have a role of stopping cracks that occur when a wafer is diced to cut out segmentalized semiconductor chips, and a role of stopping infiltration of contaminants such as impurity ions from the outside. The edge seals ES1 to ES6 are provided so as to surround the entire memory region R_{M}, but may be provided only in a part of the memory region R_{M}. However, at least one of the edge seals ES2 and ES3 is provided so as to surround the entire memory region R_{M}. The edge seals ES1 to ES6 are also called a guard ring or a seal ring, or may be called a crack stopper.

The edge seal ES1 is an edge seal that is provided at the innermost periphery (an edge seal closest to the memory region side in the edge seal region R_{ES}) as viewed in the Z-direction among the edge seals ES1 to ES6. The edge seal ES1 is connected to the wirings ch, m0, and m1, but is not connected to the bonding electrode P_{I1} of the wiring layer MB.

Specifically, as shown in FIG. 10, the edge seal ES1 is connected to the wiring ch at a position overlapping with the wiring ch as viewed in the Z-direction, and is electrically connected to the wirings Vy, m0, V1, and m1 at positions overlapping with the wirings Vy, m0, V1, and m1 as viewed in the Z-direction. However, the edge seal ES1 is not electrically connected to the bonding electrode P_{I1}. Furthermore, the bonding electrode P_{I1} is not provided below the edge seal ES1.

The edge seals ES2 and ES3 are provided on the outside of the edge seal ES1 as viewed in the Z-direction. In the example shown in FIG. 10, the edge seal ES3 is provided on the outside of the edge seal ES2 as viewed in the Z-direction. The edge seals ES2 and ES3 are connected to the wiring layers CH, M0, M1, and MB. Specifically, as shown in FIG. 10, the edge seals ES2 and ES3 are connected to the wirings ch at positions overlapping with the wirings ch as viewed in the Z-direction, and are electrically connected to the wirings Vy, m0, V1, m1, VB, and the bonding electrode P_{I1} at positions overlapping with the wirings Vy, m0, V1, m1, VB, and the bonding electrode P_{I1} as viewed in the Z-direction. The edge seals ES2 and ES3 are further electrically connected to the bonding electrode P_{I2} and a plurality of wirings d0, d1, d2, d3, and d4 on the chip C_{P}. Furthermore, the edge seals ES2 and ES3 are also connected to the wirings ma on the back surface wiring layer MA. As a result, the edge seals ES2 and ES3 can release (neutralize) charges that accumulates during the manufacturing process of the chip C_{M} through the semiconductor substrate on which the chip C_{M} is formed. Furthermore, the edge seals ES2 and ES3 can restrain impurities such as hydrogen from entering the memory region R_{M} from the outside.

The edge seal ES5 is provided on the outside of the edge seal ES3 as viewed in the Z-direction. The edge seal ES5 is connected to the wirings ch, m0, and m1, but is not connected to the bonding electrode P_{I1} of the wiring layer MB. Specifically, as shown in FIG. 10, the edge seal ES5 is connected to the wiring ch at a position overlapping with the wiring ch as viewed in the Z-direction, and is electrically connected to the wirings Vy, m0, V1, and m1 at positions overlapping with the wirings Vy, m0, V1, and m1 as viewed in the Z-direction. However, the edge seal ES5 is not electrically connected to the bonding electrode P_{I1}. The edge seal ES5 can restrain impurities such as hydrogen from entering the memory region R_{M} from the outside. Furthermore, the edge seal ES5 can restrain cracks or peeling occurring from the kerf region R_{K} on the outer edge of the chip during the dicing step from propagating to the memory region R_{M}.

Among the edge seals ES1 to ES6, the edge seal ES6 is provided at the outermost periphery (at a position closest to the kerf region R_{K} within the edge seal region RES) as viewed in the Z-direction. The edge seal ES6 is connected to the wiring ch, but is not connected to the wiring m1. Specifically, the wiring layers M0 and MB are not provided below the edge seal ES6, and the wiring m1 of the wiring layer M1 which is spaced apart from the edge seal ES6 and is not electrically connected thereto is provided below the edge seal ES6.

### Manufacturing Method

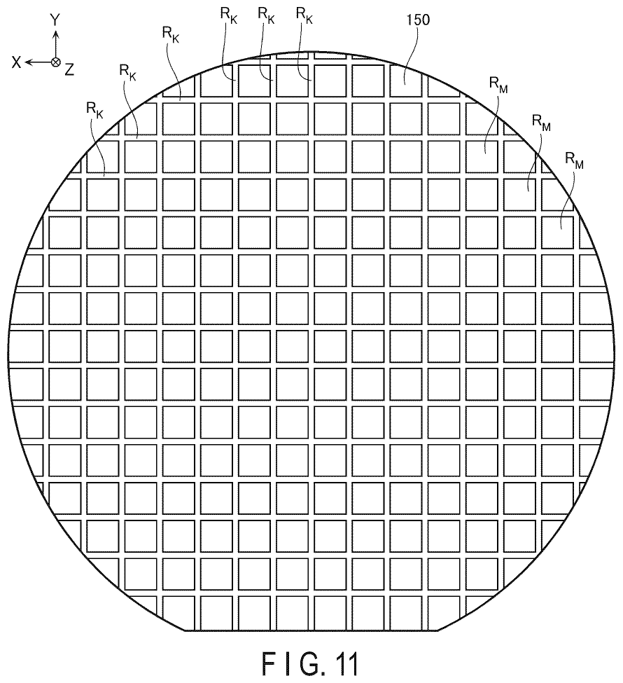

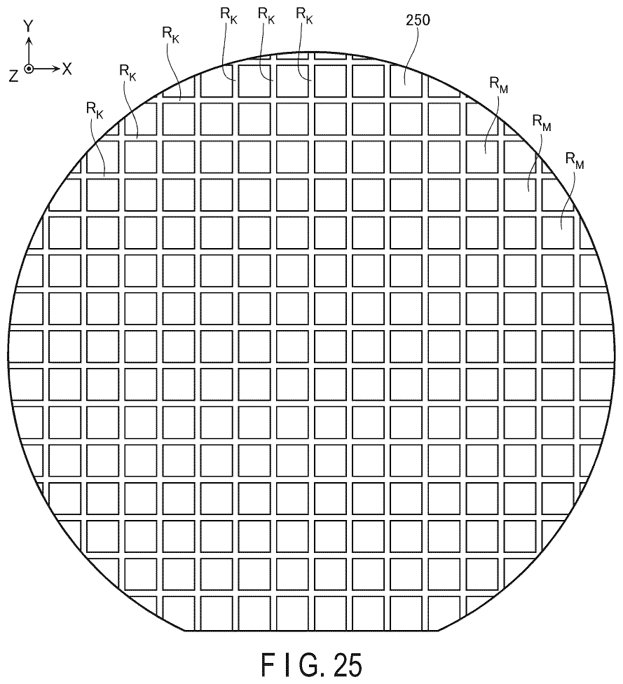

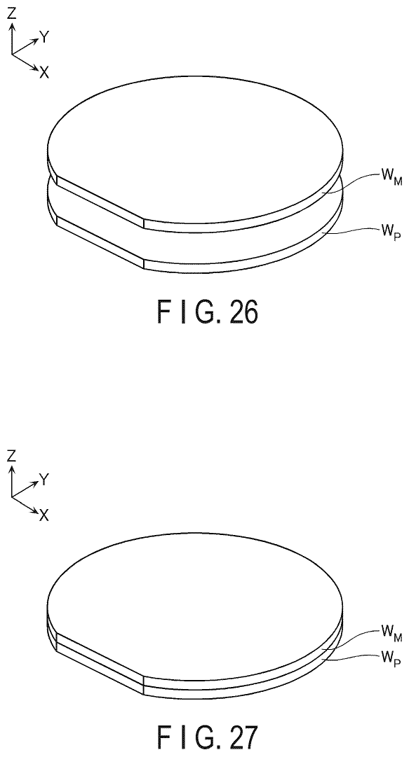

Next, a method for manufacturing a memory die MD will be described with reference to FIGS. 11 to 30. FIGS. 11 and 25 are bottom view diagrams for describing the manufacturing method. FIGS. 12 to 24 are cross sectional diagrams for describing the manufacturing method. FIGS. 26 and 27 are perspective view diagrams for describing the manufacturing method. FIGS. 12 to 24 show cross sectional views corresponding to FIG. 10.

When the memory die MD according to the present embodiment is manufactured, a wafer W_{M} corresponding to the chip C_{M} and a wafer W_{P} corresponding to the chip C_{P} are manufactured (see FIG. 26), and these two wafers W_{M} and W_{P} are bonded together (see FIG. 27). After a back surface wiring layer MA (FIG. 7), etc. are formed, the segmentation into individual pieces by dicing is performed.

### Method for Manufacturing Wafer W_{M}

FIG. 11 shows the surface of a semiconductor substrate 150 corresponding to the wafer W_{M}. As shown in FIG. 11, the surface of the semiconductor substrate 150 is provided with a plurality of memory regions R_{M} and kerf regions R_{K} provided among the plurality of memory regions R_{M}. The plurality of memory regions R_{M} become memory dies MD after dicing. The configuration in the kerf region R_{K} is not used for inputting/outputting a voltage to/from the memory cell array or inputting/outputting a data signal or other signals to/from the memory cell array.

When the wafer W_{M} is manufactured, as shown in FIG. 12, for example, an insulating layer 112 of silicon oxide (SiO₂) or the like is formed on the surface of the semiconductor substrate 150. Next, a semiconductor layer 100A of silicon or the like is formed on the surface of the insulating layer 112. This step is performed, for example, by chemical vapor deposition (CVD), thermal oxidation or the like. These steps are performed by CVD or the like or thermal oxidation or the like.

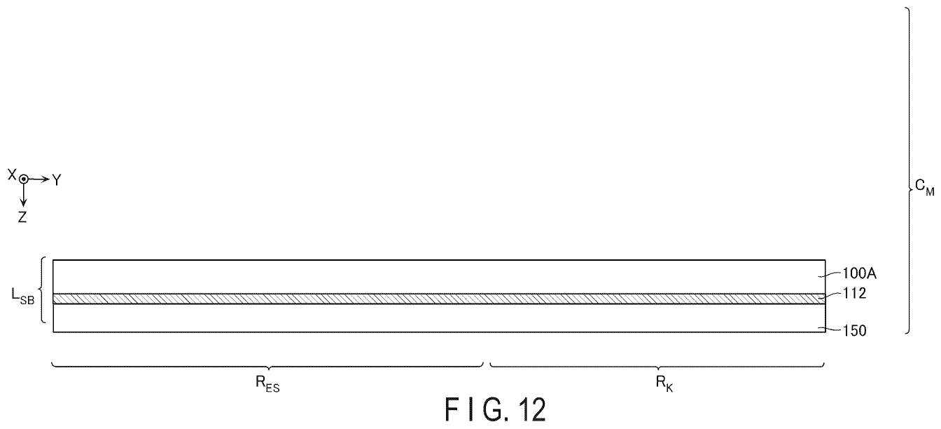

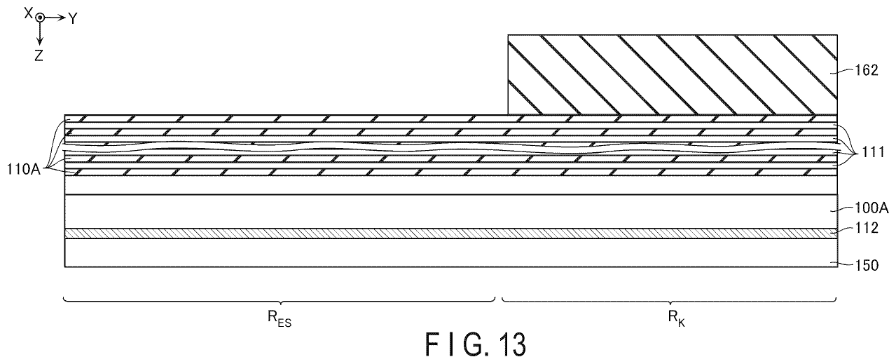

Next, as shown in FIG. 13, for example, a plurality of insulating layers 111 and a plurality of sacrificial layers 110A are alternately formed on the semiconductor layer 100A in the edge seal region R_{ES} and the kerf region R_{K} by a method such as chemical vapor deposition (CVD). Furthermore, a resist 162 is formed in a part of the region excluding the edge seal region R_{ES}.

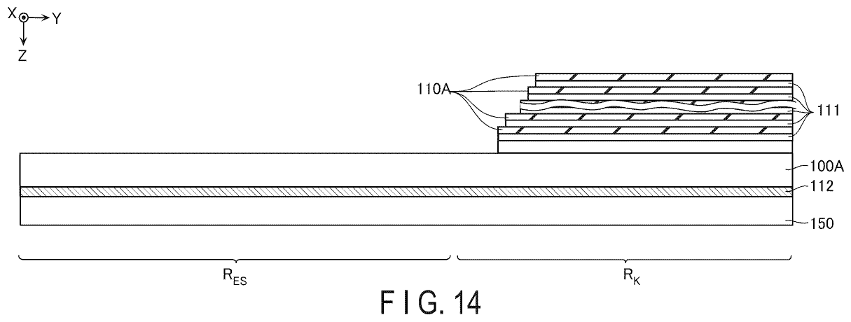

Next, each of removal of the sacrificial layers 110A and removal of the insulating layers 111 is performed once, and a part of the resist 162 is repeatedly removed, thereby forming a step-like structure for connecting the conductive layers 110 described with reference to FIG. 8, etc. to contact electrodes (not shown). In the example of FIG. 14, a step-like structure is also formed in the boundary portion between the kerf region R_{K} and the edge seal region R_{ES}. These steps are performed by a method such as wet etching, dry etching or the like.

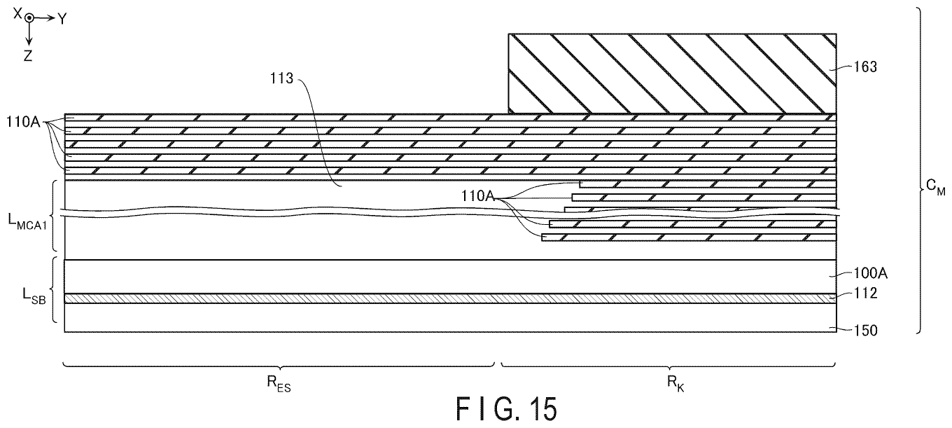

Next, for example, as shown in FIG. 15, an insulating layer 113 is formed in the edge seal region R_{ES} and the kerf region R_{K} on the surface of the structure shown in FIG. 14 of the kerf region R_{K}. Next, a plurality of insulating layers 111 and a plurality of sacrificial layers 110A are formed alternately. These steps are performed, for example, by a method such as CVD. Furthermore, a resist 163 is formed in a partial region excluding the edge seal region R_{ES}.

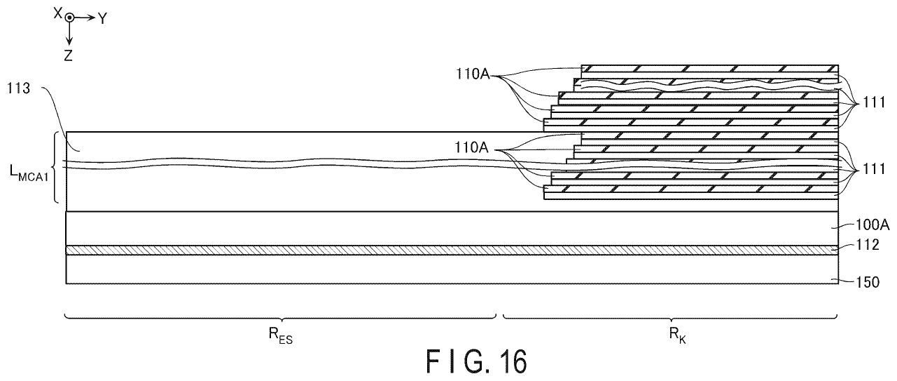

Next, each of removal of the sacrificial layers 110A and removal of the insulating layers 111 is performed once, and a part of the resist 163 is repeatedly removed, thereby forming the above-mentioned step-like structure. It is noted that, in the example of FIG. 16, a step-like structure is also formed in the boundary portion between the kerf region R_{K} and the edge seal region R_{ES}. These steps are performed, for example, by a method such as wet etching, dry etching or the like.

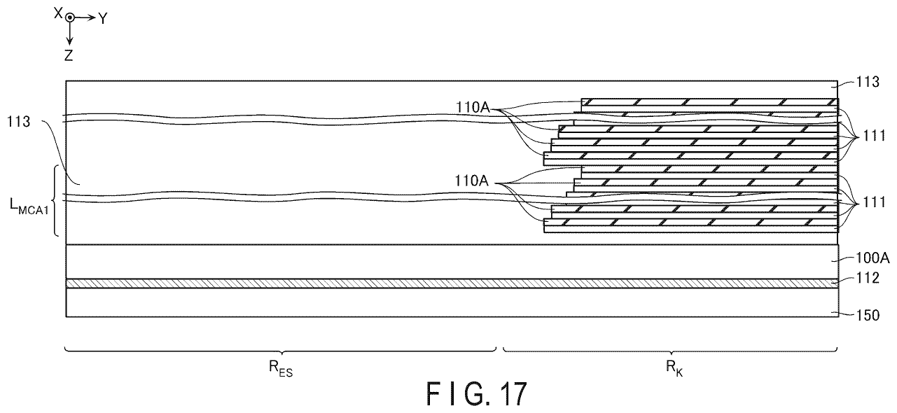

Next, for example, as shown in FIG. 17, an insulating layer 113 of silicon oxide (SiO₂) or the like is formed on the surface of the structure shown in FIG. 16. This step is performed, for example, by CVD or the like.

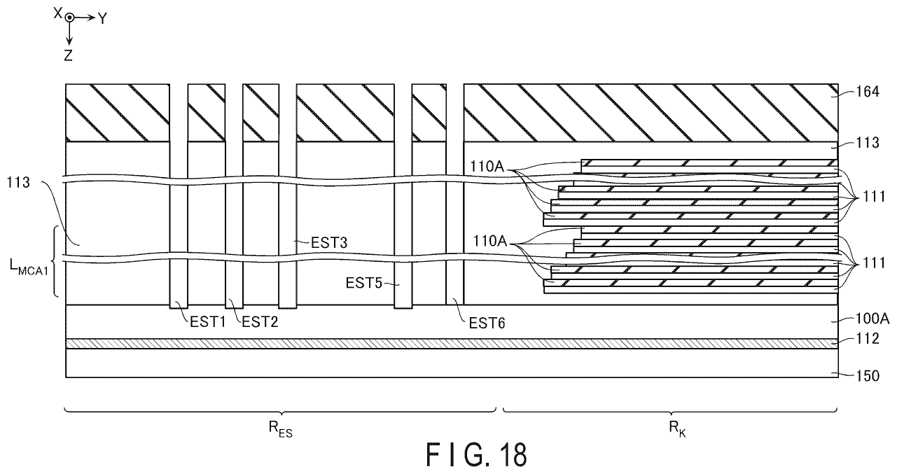

Next, for example, as shown in FIG. 18, a resist 164 in which the region corresponding to the edge seals ES1 to ES6 (FIG. 10) is opened is formed, the insulating layer 113 at the positions corresponding to the edge seals ES1 to ES6 is removed, thereby forming grooves EST1 to EST6. The grooves EST1 to EST6 extend in the Z-direction and the X-direction, and penetrate the insulating layer 113 to expose the surface of the semiconductor layer 100A. This step is performed, for example, by a method such as reactive ion etching (RIE). Although not shown, the grooves EST1 to EST6 are formed at the same time as grooves that will serve as the inter-block structures ST (FIG. 7) of the memory plane region R_{MP} and the kerf region R_{K}. Although not shown in the figures, grooves are also formed in the kerf region R_{K} in this step.

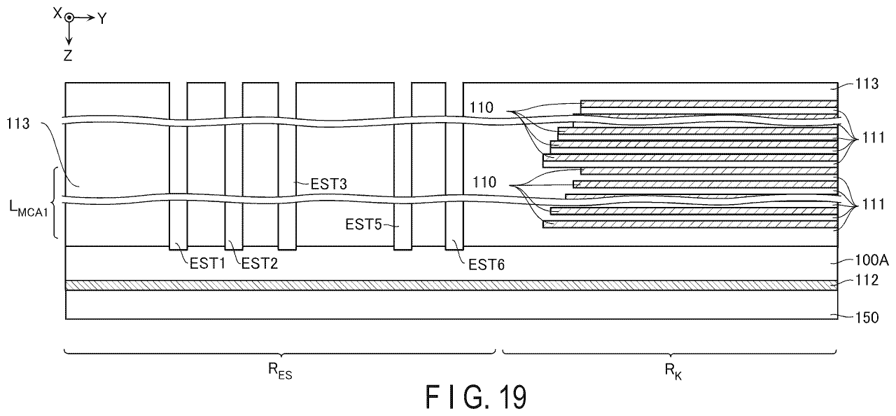

Next, for example, as shown in FIG. 19, the sacrificial layers 110A are removed through the grooves formed in the step described with reference to FIG. 18 to form the conductive layers 110. As a result, the sacrificial layers 110A are replaced with the conductive layers 110. The step of removing the sacrificial layers 110A is performed, for example, by a method such as wet etching, and the step of forming the conductive layers 110 is performed, for example, by a method such as CVD. Thereafter, the inter-block structures ST are formed in the grooves that will serve as the inter-block structures ST (FIG. 7), and the edge seals ES1 to ES6 are formed in the grooves EST1 to EST6. This step is performed, for example, by a method such as CVD and RIE.

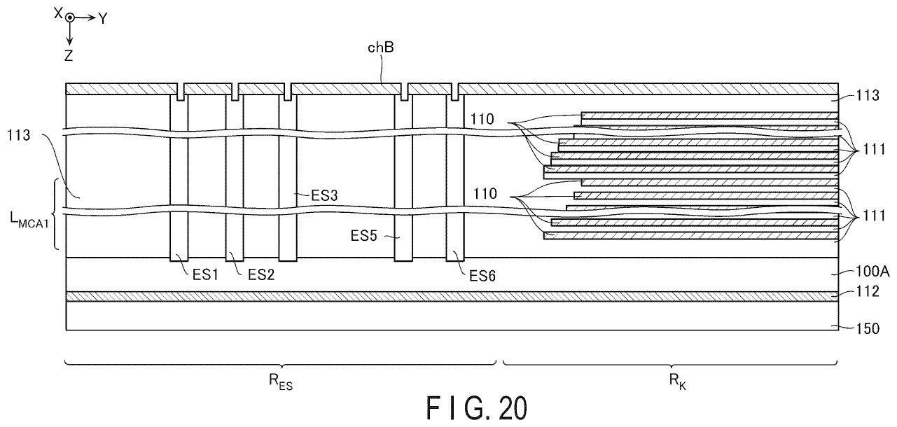

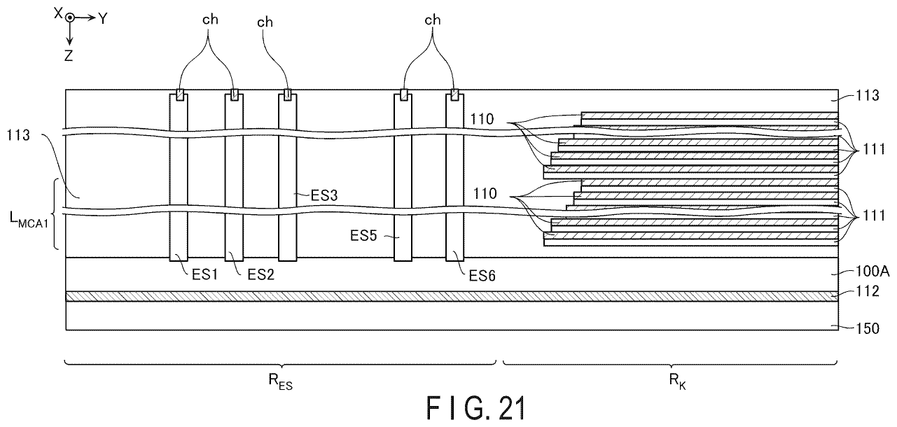

Next, as shown in FIGS. 20 and 21, the wirings ch are formed by a damascene process.

For example, as shown in FIG. 20, through-holes are formed at positions corresponding to the wirings ch so as to expose one ends of the edge seals ES1 to ES6, and a conductive layer chB is formed inside the through-holes and on the surface of the insulating layer 113. The formation of the through-holes is performed by a method such as RIE. The formation of the conductive layer chB is performed by a method such as CVD.

Next, for example, as shown in FIG. 21, a part of the conductive layer chB is removed to form a plurality of wirings ch. This step is performed by a method such as chemical mechanical polishing (CMP).

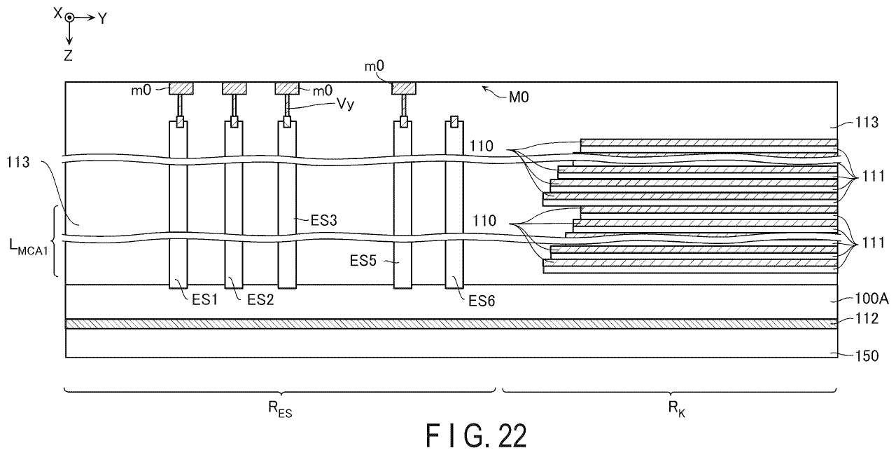

Next, for example, as shown in FIG. 22, a wiring layer M0 is formed by a damascene process. In this step, wirings Vy and wirings m0 are formed on the wirings ch formed in the edge seals ES1 to ES5 by using physical vapor deposition (PVD) or the like. On the other hand, neither a wiring Vy nor a wiring m0 is formed on the wiring ch formed on the edge seal ES6.

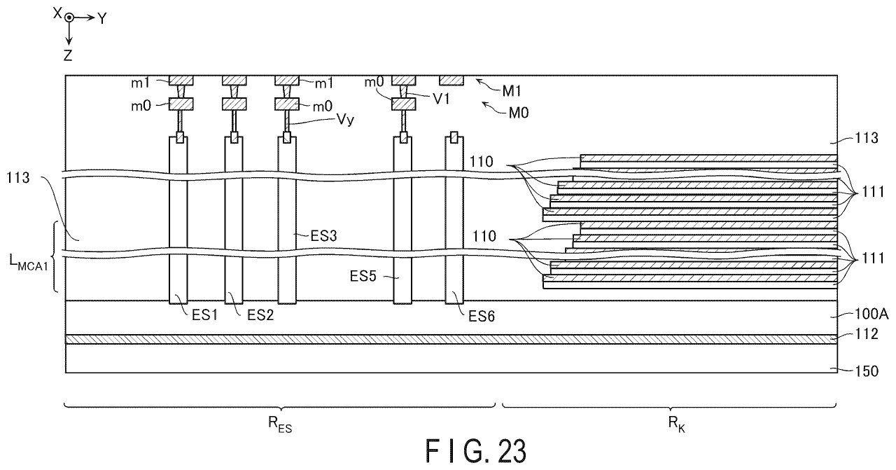

Next, for example, as shown in FIG. 23, a wiring layer M1 is formed by a damascene process. In this step, wirings V1 and wirings m1 are formed on the wirings m0 formed above the edge seals ES1 to ES5 (in the −Z-direction in FIG. 23) by using PVD or the like. On the other hand, no wiring V1 is formed above the edge seal ES6 (in the −Z-direction in FIG. 23), and only the wiring m1 is formed above the edge seal ES6, so that the wiring m1 above the edge seal ES6 is formed in a floating state while spaced apart from the edge seal ES6.

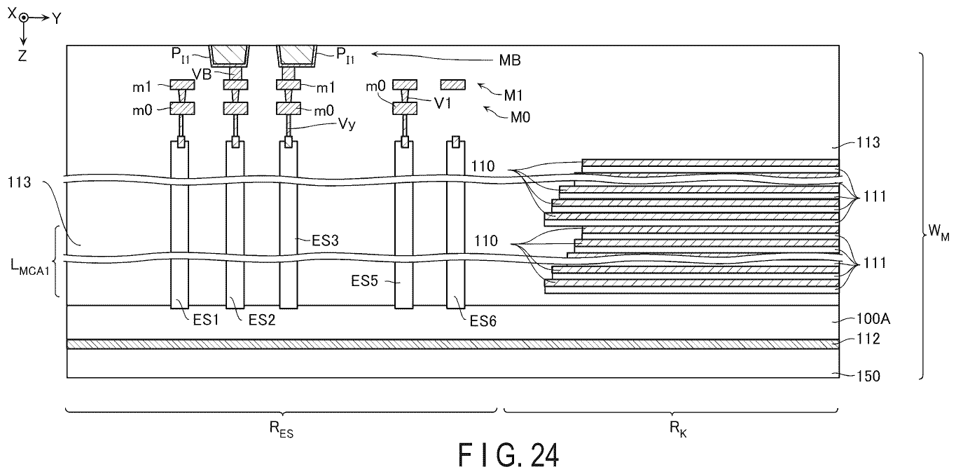

Next, for example, as shown in FIG. 24, a wiring layer MB is formed by a damascene process. In this step, wirings VB are formed on the wirings m1 formed above the edge seals ES2 to ES3 by using PVD or the like. Furthermore, bonding electrodes P_{I1} are formed on the wirings VB formed above the edge seals ES2 and ES3 by using PVD or the like. On the other hand, no bonding electrode P_{I1} is formed above the edge seals ES1, ES5, and ES6.

### Method of Manufacturing Wafer W_{P}

FIG. 25 shows the surface of a semiconductor substrate 250 corresponding to the wafer W_{P}. As shown in FIG. 25, the surface of the semiconductor substrate 250 is also provided with a plurality of memory regions R_{M} and kerf regions R_{K} provided between the plurality of memory regions R_{M}, like the surface of the semiconductor substrate 150. The respective configurations on the wafer W_{P} are formed by a film formation step such as CVD, a patterning step such as photolithography, and processing steps such as etching and CMP.

### Step of Bonding Wafers W_{M} and W_{P} and Subsequent Steps

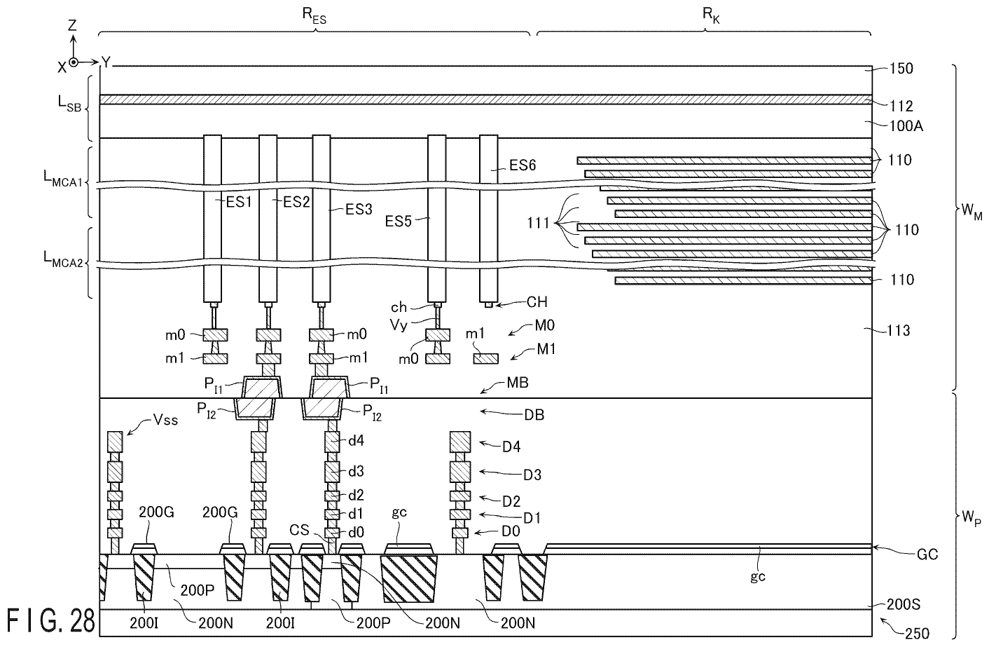

After the wafers W_{M} and W_{P} are manufactured, the wafers W_{M} and W_{P} are placed such that the surface of the wafer W_{M} and the surface of the wafer W_{P} face each other as shown in FIG. 26, for example. For example, as shown in FIGS. 27 and 28, the wafers W_{M} and W_{P} are bonded together. In this bonding step, for example, the wafer W_{M} is pressed against the wafer W_{P} such that the wafer W_{M} is brought into close contact with the wafer W_{P}, and a heat treatment or the like is performed. As a result, the wafer W_{M} is bonded to the wafer W_{P} via the bonding electrodes P_{I1} and P_{I2}.

Next, the semiconductor substrate 150 and the insulating layer 112 of the wafer W_{M} are removed.

Next, a back surface wiring layer MA and the like are formed to form the base structure L_{SB} described with reference to FIG. 10.

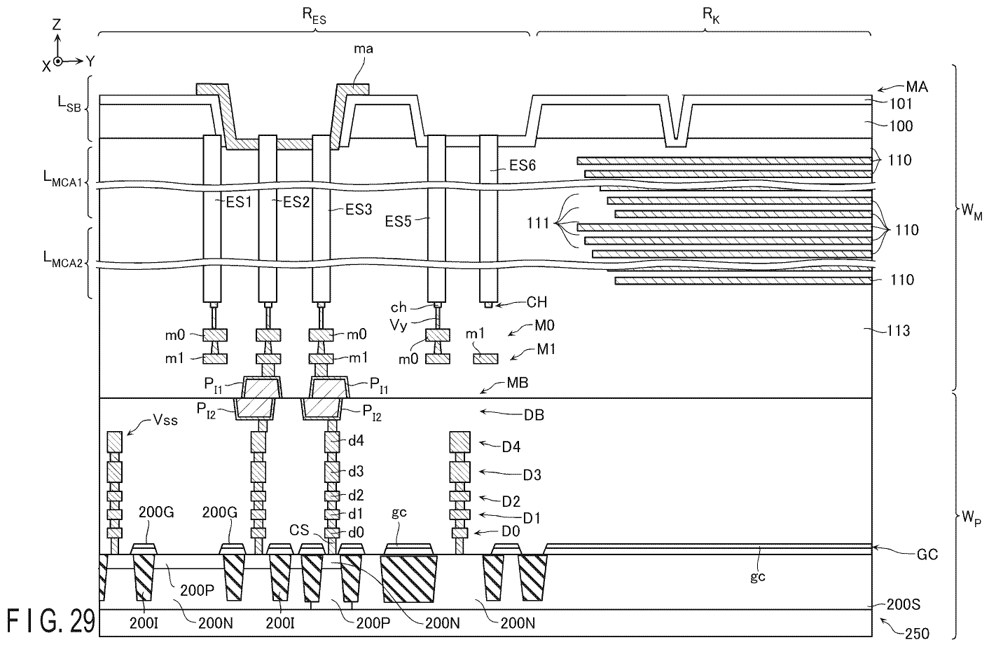

Specifically, for example, as shown in FIG. 29, a part of the semiconductor layer 100A is removed to form contact holes corresponding to the positions of the edge seals ES1 to ES6. This step is performed, for example, by a method such as RIE. Next, the insulating layer 101 is formed. This step is performed, for example, by a method such as CVD. Next, the insulating layer 101 is removed in the contact holes corresponding to the positions of the edge seals ES1 to ES6. As a result, the edge seals ES1 to ES6 are exposed. This step is performed, for example, by a method such as RIE. Next, a metal layer is formed on the upper surface of the insulating layer 101, the side surfaces of the insulating layer 101 in the X-direction and the Y-direction (including the inner peripheral surfaces of the contact holes), and the upper surface of the insulating layer 113, for example, by a method such as CVD, and a part of the formed metal layer is removed by a method such as RIE to form the wirings ma. This step is performed, for example, by a method such as RIE.

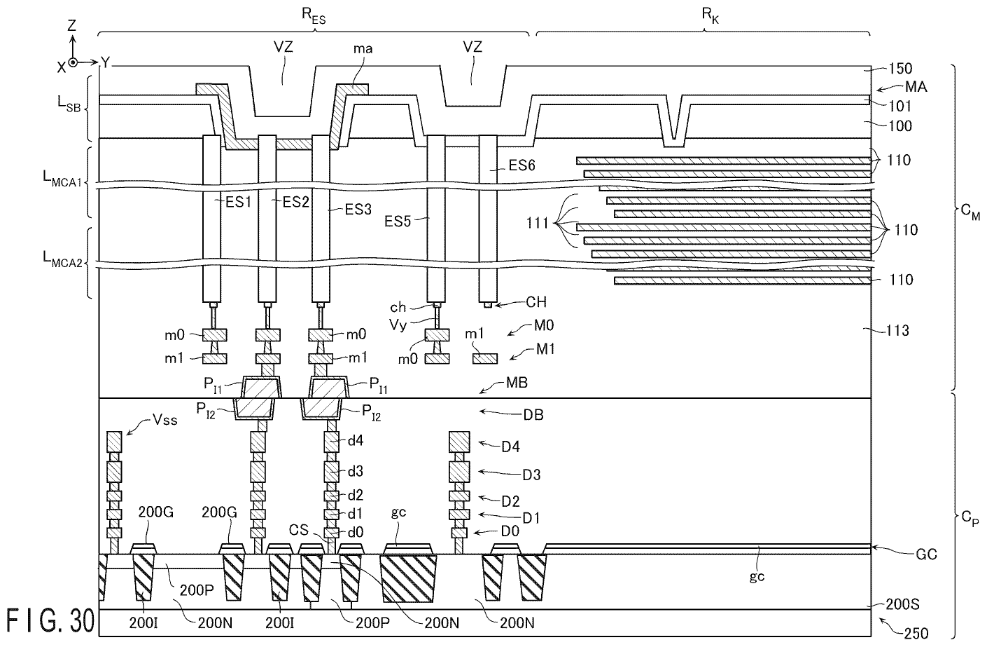

Next, for example, as shown in FIG. 30, an insulating layer 102 is formed on the upper surface of the insulating layer 101, the upper surface of the wiring ma, and the side surfaces of the wiring ma in the X-direction and Y-direction (including the inner peripheral surface inside the contact hole). This step is performed, for example, by a method such as CVD.

Thereafter, the bonded wafers W_{M} and W_{P} are cut along dicing lines provided in the kerf region R_{K}. As a result, each of the configurations provided in each memory die region R_{MD} serves as the memory die MD. It is noted that a part of the kerf region R_{K} may serve as a part of the memory die MD as the kerf region R_{K} described with reference to FIG. 10.

### Effect of First Embodiment

In the first embodiment, as shown in FIG. 10 and the like, the chip C_{P} and the chip C_{M} include the edge seal region R_{ES} that is provided so as to surround the memory region R_{M}, and the kerf region R_{K} that is provided outside the edge seal region R_{ES}. The edge seal region R_{ES} is provided with the plurality of edge seals ES1 to ES6 that extend along the Z-direction, are provided so as to surround the periphery of the memory region RM as viewed in the Z-direction, and are spaced apart from each other from the inner peripheral side to the outer peripheral side of the edge seal region R_{ES}. The edge seals ES1 to ES5 are connected to the wirings m0 of the wiring layer M0 and the wirings m1 of the wiring layer M1. On the other hand, the wiring m1 of the wiring layer M1 which is not electrically connected to the edge seal ES6 and is spaced apart from the edge seal ES6 in the Z-direction is provided below the edge seal ES6 that is the outermost periphery.

Here, as described above, at least one of the edge seals ES2 and ES3 is provided so as to completely surround the periphery of the memory region R_{M}. Furthermore, the edge seals ES2 and ES3 are connected to a region extending from the lower surface of the base structure L_{SB} to the upper surface of the semiconductor substrate 200 via the wiring layers CH, M0, M1, and MB and the plurality of wiring layers D0 to D4 and DB in the chip C_{P}. As a result, the edge seals ES2 and ES3 can release (neutralize) the charges accumulated during the manufacturing process of the chip C_{M} via the semiconductor substrate on which the chip C_{M} is formed. Furthermore, the edge seals ES2 and ES3 can restrain impurities such as hydrogen from entering the memory region from the outside.

Furthermore, the edge seal ES1 is provided on the inner peripheral side of the edge seals ES2 and ES3, and the edge seals ES5 and ES6 are provided on the outer peripheral side of the edge seals ES2 and ES3. This makes it possible to accurately open the regions corresponding to the edge seals ES2 and ES3 in the step described with reference to FIG. 18, so that the edge seals ES2 and ES3 can be suitably manufactured.

Here, in the step described with reference to FIG. 27, it is desirable that a certain percentage or more of the insulating layer 113 is exposed on the surfaces of the wafers W_{M} and W_{P}. This is because when the wafers W_{M} and W_{P} are bonded together, the insulating layers 113 of the wafers W_{M} and W_{P} are connected to each other. For this reason, the edge seals ES1, ES5, and ES6 are not connected to the bonding electrode P_{I1}. Furthermore, in order to suitably bond the wafers W_{M} and W_{P}, it is desirable that the surfaces of the wafers W_{M} and W_{P} are flat.

Here, as described with reference to FIG. 23, the wiring layer M1 is formed by a damascene process. As described above, in the damascene process, an opening is formed in an insulating layer, a conductive layer is formed in the opening and on the upper surface of the insulating layer, and then the conductive layer formed on the upper surface of the insulating layer is removed by flattening means such as CMP while leaving the conductive layer in the opening. Here, when flattening means such as CMP is performed, if the density (coverage rate) of the conductive layer in the opening is not constant, unevenness may occur on the surfaces of the wafers W_{M}, W_{P}.

In particular, in the present embodiment, the wirings m0 in the wiring layer M0 contain copper, and the wirings m1 in the wiring layer M1 contain tungsten. Furthermore, the tungsten corresponding to the wiring m1 is formed by PVD. This is because the wirings m0 contain copper and thus it is difficult to use a high-temperature process. In such a case, the above unevenness problem is particularly likely to occur due to the quality of the formed tungsten film.

To address such issues, in the present embodiment, the wiring m1 of the wiring layer M1 is provided below the edge seal ES6 which is the outermost periphery. As a result, the coverage rate of the wiring layer M1 below the edge seal ES6 is not sparse as compared with a case where the wiring m1 of the wiring layer M1 is not provided below the edge seal ES6, so that it is possible to reduce the difference in coverage rate between the edge seal region R_{ES} and other regions in the chip C_{M}. Therefore, as compared with the case where the wiring m1 of the wiring layer M1 is not provided below the edge seal ES6, it is possible to reduce the steps between the edge seal region R_{ES} and the other regions, enhance the accuracy of the bonding step of bonding the wafers W_{M} and W_{P}, and improve the yield of semiconductor storage devices.

However, the edge seal ES6 is provided on the outermost peripheral side among the edge seals ES1 to ES6 in the edge seal region R_{ES}. Therefore, for example, in the step described with reference to FIG. 20, when the edge seal ES6 is formed, the inside of the groove EST6 may not be filled with a material such as tungsten or silicon oxide, resulting in the formation of a recess portion. Therefore, when all of the wirings ch, m0, and m1 in the wiring layers CH, M0, and M1 are formed above the edge seal ES6 (in the −Z-direction), there is a risk that unevenness may be formed on the surface of the wafer W_{M} by the effect of the recess portion.

To address such issues, in the first embodiment, the wirings ch and m0 in the wiring layers CH and M0 are omitted below the edge seal ES6 (in the −Z-direction). According to such a method, it is possible to flatten the region on the front surface side (negative side in the Z-direction) of the edge seal ES6 by using the insulating layer 113 and the like during a period of time from the formation of the edge seal ES6 until the formation of the wiring m1 in the wiring layer M1.

### EXAMPLE 1

In the first embodiment, for example, as shown in FIG. 10, it is described that the width in the Y-direction of the wiring m1 of the floated wiring layer M1 provided below the edge seal ES6 is approximately equal to the width in the Y-direction of the edge seal ES6, but the first embodiment is not limited to the above configuration. Examples 1 to 4 of the first embodiment will be hereinafter described while applying a case in which the width in the Y-direction of the floated wiring layer M1 provided below the edge seal ES6 is larger than the width in the Y-direction of the edge seal ES6.

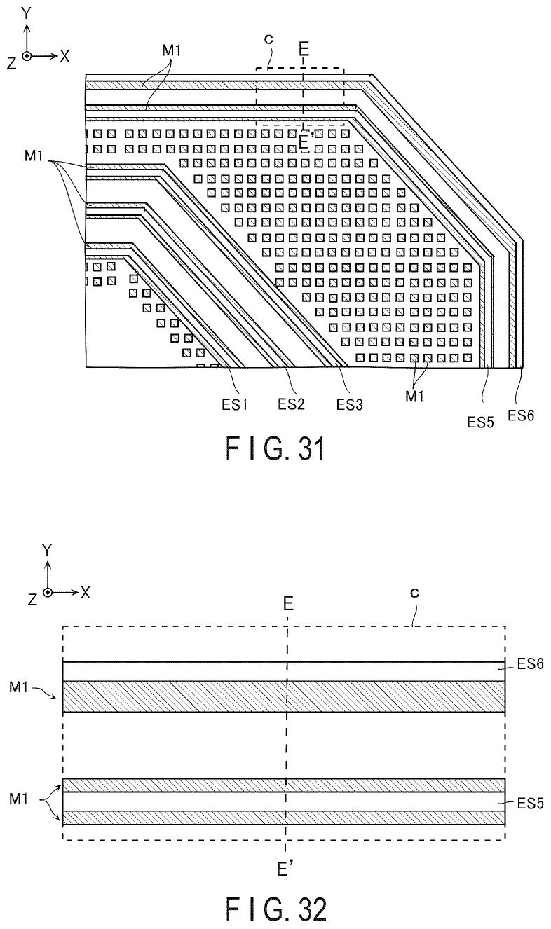

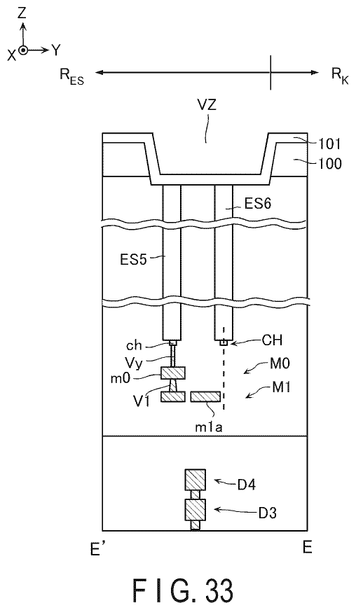

FIG. 31 is a plan view diagram schematically showing the arrangement of a plurality of edge seals ES1 to ES6 in an edge seal region R_{ES} and the arrangement of wiring layers M1 according to Example 1 of the first embodiment. FIG. 32 is a plan view diagram schematically showing an enlarged part of FIG. 31. FIG. 32 shows an enlarged partial region c of FIG. 31. FIG. 33 is a cross sectional diagram schematically showing the structure of the wiring layer M1 provided below the edge seal ES6, which is taken along a dotted line E-E′ in FIG. 31. The same configurations as those in FIG. 10 are given the same reference signs, and duplicated descriptions thereon will be omitted.

In the edge seal region R_{ES}, as shown in FIG. 31, a dummy pattern of a plurality of island-shaped wiring layers M1 arranged side by side in the X-direction and the Y-direction may be formed. FIG. 31 shows an example of the dummy pattern of the plurality of wiring layers M1 arranged side by side at a predetermined pitch in the X-direction and the Y-direction.

Furthermore, in the edge seal region R_{ES}, as shown in FIG. 31, the edge seals ES1 to ES6 may be provided in a ring shape so as to surround the periphery of the memory region R_{M} (not shown). Still furthermore, the wiring layers M1 are arranged so as to overlap with the edge seals ES1 to ES5 as viewed in the Z-direction.

The edge seals ES1 to ES5 are located near the center of the wiring layers M1 as viewed in the Z-direction. As shown in FIGS. 31 and 32, the widths of the wiring layers M1 overlapping with the edge seals ES1 to ES5 as viewed in the Z-direction are equal to or more than the widths of the edge seals ES1 to ES5. On the other hand, as shown in FIGS. 31 and 32, the edge seal ES6 is located at one end portion of the wiring layer M1 whose width is larger than the width of the edge seal ES6 as viewed in the Z-direction. The width in the Y-direction of the wiring m1a of the floated wiring layer M1 provided below the edge seal ES6 is larger than the width in the Y-direction of the edge seal ES6 as shown in FIG. 33. It is noted that the edge seal ES6 may be arranged so as to overlap with a part of the one end portion of the wiring layer M1 as viewed in the Z-direction as shown in FIG. 33, but it may also be arranged so as not to overlap with the wiring layer M1.

According to such configurations, Example 1 makes it possible to provide the wiring layer M1 below the edge seal ES6 in consideration of the processing accuracy (processing variation) of the edge seal ES6.

Furthermore, the width in the Y-direction of the wiring layer M1 below the edge seal ES6 is set to be larger than the width in the Y-direction of the edge seal ES6, whereby it is possible to enhance the coverage rate of the wiring layer M1 in the Z-direction of the edge seal ES6. As a result, it is possible to reduce the difference in coverage rate of the wiring layer M1 between the edge seal region R_{ES} and the end portion of the kerf region R_{K} in the chip C_{M}.

In FIGS. 31 and 32, when the edge seal ES6 is viewed in the Z-direction, the wiring layer M1 whose width is larger than the width of the edge seal ES6 is visible, but Example 1 is not limited to this configuration. The wiring layer M0 or the wiring layer V1 may also be visible. In this case, when viewed in the Z-direction, for example, the wiring layer M0, the wiring layer V1, or the wiring layers M0 and V1 are arranged between the edge seal ES6 and the wiring layer M1 shown in FIG. 33.

### Example 2

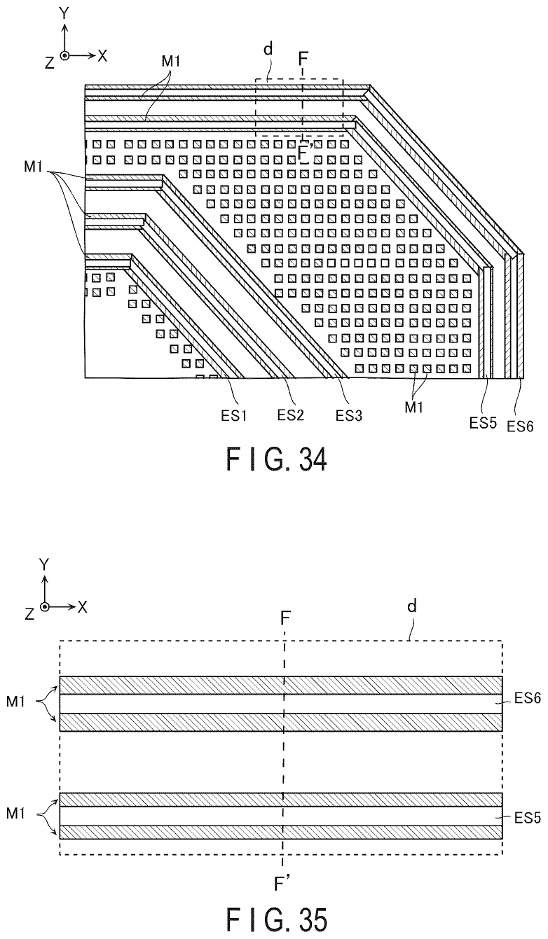

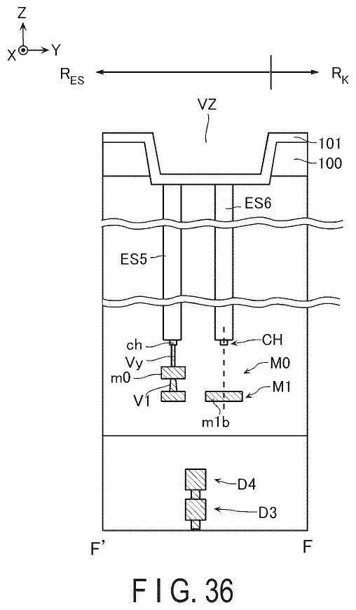

FIG. 34 is a plan view diagram schematically showing the arrangement of edge seals ES1 to ES6 in an edge seal region R_{ES} and the arrangement of wiring layers M1 in Example 2 of the first embodiment. FIG. 35 is a plan view diagram schematically showing an enlarged part of FIG. 34. In FIG. 35, an enlarged partial region d of FIG. 34 is shown. FIG. 36 is a cross sectional diagram schematically showing the structure of the wiring layer M1 provided below the edge seal ES6 which is taken along a dotted line F-F′ in FIG. 34. The same configurations as those in FIG. 31 to FIG. 33 are given the same reference signs, and duplicated descriptions thereon will be omitted.

In the edge seal region R_{ES}, as shown in FIG. 34, the edge seals ES1 to ES6 are provided in a ring shape so as to surround the periphery of a memory region R_{M} (not shown), and the wiring layers M1 are arranged so as to overlap with the edge seals ES1 to ES6 as viewed in the Z-direction.

For example, as shown in FIGS. 35 and 36, the edge seal ES6 is located near the center of the wiring layers M1 as viewed in the Z-direction. As viewed in the Z-direction, the width of the wiring m1b of the wiring layer M1 that overlaps with the edge seal ES6 is larger than the width of the edge seal ES6.

As described above, the width in the Y-direction of the wiring layer M1 below the edge seal ES6 is set to be larger than the width in the Y-direction of the edge seal ES6, whereby it is possible to enhance the coverage rate of the wiring layer M1 in the Z-direction of the edge seal ES6. As a result, it is possible to reduce the difference in coverage rate of the wiring layer M1 between the edge seal region R_{ES} and the end portion of the kerf region R_{K} in the chip C_{M}.

In FIGS. 34 and 35, the wiring layer M1 is visible when the edge seal ES6 is viewed in the Z-direction, but Example 2 is not limited to this configuration. The wiring layer M0 or the wiring layer V1 may also be visible. In this case, when viewed in the Z-direction, the wiring layer M0, the wiring layer V1, or the wiring layers M0 and V1 are arranged between the edge seal ES6 and the wiring layer M1 shown in FIG. 36, for example.

### Example 3

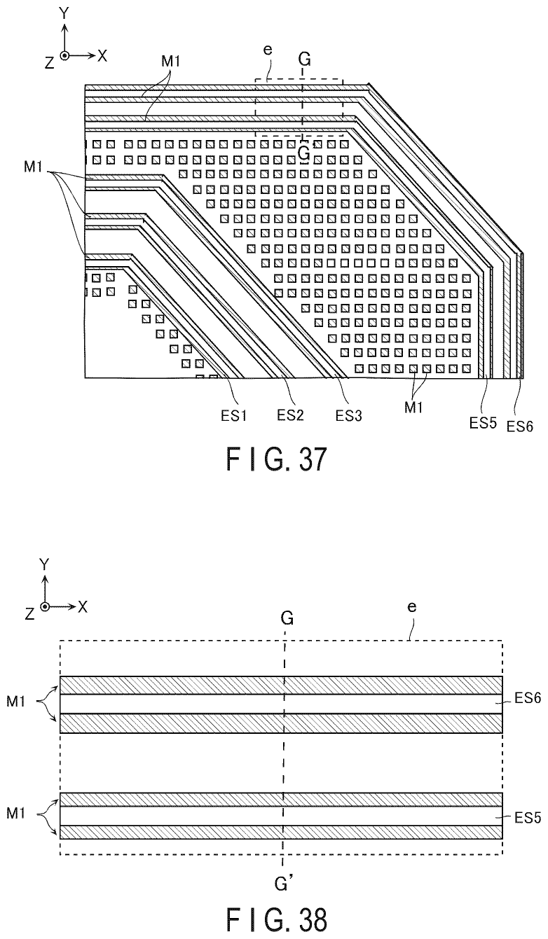

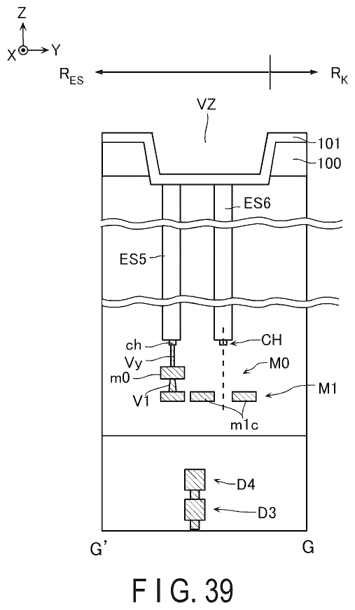

FIG. 37 is a plan view diagram schematically showing the arrangement of a plurality of edge seals ES1 to ES6 in an edge seal region R_{ES} and the arrangement of wiring layers M1 according to Example 3 of the first embodiment. FIG. 38 is a plan view diagram schematically showing an enlarged part of FIG. 37. In FIG. 38, an enlarged partial region e of FIG. 37 is shown. FIG. 39 is a cross sectional diagram schematically showing the structure of the wiring layer M1 provided below the edge seal ES6 which is taken along a dotted line G-G′ in FIG. 37. The same configurations as those in FIG. 31 to FIG. 33 are given the same reference signs, and duplicated descriptions thereon will be omitted.

In the edge seal region R_{ES}, as shown in FIG. 37, the edge seals ES1 to ES6 are arranged in a ring shape so as to surround the periphery of the memory region R_{M} (not shown), and the wiring layers M1 are arranged so as to overlap with the edge seals ES1 to ES5 as viewed in the Z-direction.

The wiring layer M1 provided below the edge seal ES6 (in the −Z-direction) is located near both sides of the edge seal ES6 as shown in FIG. 37 to FIG. 39, for example. Furthermore, for example, as shown in FIG. 39, a plurality of wiring layers M1 are provided below the edge seal ES6 as viewed in the Z-direction, but the total width in the Y-direction of a plurality of wirings m1c of the floated wiring layers M1 is larger than the width in the Y-direction of the edge seal ES6. As shown in FIG. 39, the plurality of wirings m1c may be arranged so as to overlap with a part of the edge seal ES6 as viewed in the Z-direction, but may also be arranged so as not to overlap with the edge seal ES6.

As a result, even when the size in the Y-direction of the wiring layer M1 located below the edge seal ES6 cannot be set to be larger as in Examples 1 and 2, the total width in the Y-direction of the wiring layers M1 located below the edge seal ES6 can be set to be larger than the width in the Y-direction of the edge seal ES6. Therefore, the coverage rate of the wiring layer M1 in the Z-direction of the edge seal ES6 can be enhanced, so that it is possible to reduce the difference in coverage rate of the wiring layer M1 between the edge seal region R_{ES} and the end portion of the kerf region R_{K} in the chip C_{M}.

In FIGS. 37 and 38, the wiring layer M1 is visible when the edge seal ES6 is viewed in the Z-direction, but Example 3 is not limited to this configuration. The wiring layer M0 or the wiring layer V1 may also be visible. In this case, the wiring layer M0, the wiring layer V1, or the wiring layers M0 and V1 are arranged between the edge seal ES6 and the wiring layer M1 shown in FIG. 39 as viewed in the Z-direction.

### Example 4

The first embodiment and Example 1 to 3 have been described while applying the case where the floated wiring layer M1 provided below the edge seal ES6 is linearly provided as viewed in the Z-direction, but these embodiment and examples are not limited to this configuration. Example 4 will be described below while applying a case where the floated wiring layer M1 is provided so as to meander as viewed in the Z-direction.

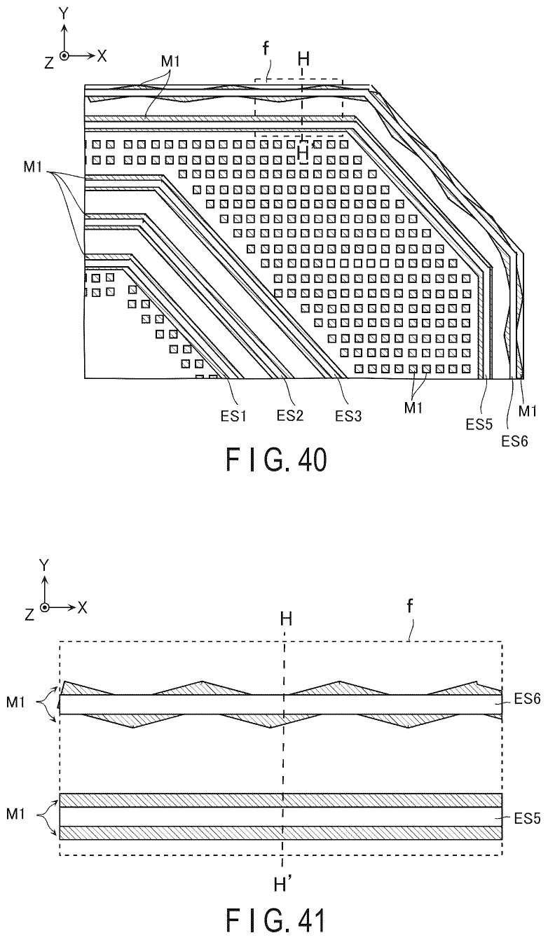

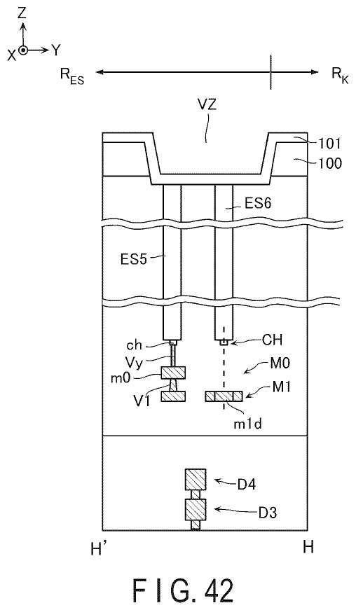

FIG. 40 is a plan view diagram schematically showing the arrangement of a plurality of edge seals ES1 to ES6 in an edge seal region R_{ES} and the arrangement of wiring layers M1 according to Example 4 of the first embodiment. FIG. 41 is a plan view diagram schematically showing an enlarged part of FIG. 40. FIG. 41 shows an enlarged partial region f of FIG. 40. FIG. 42 is a cross sectional diagram schematically showing the structure of the wiring layer M1 provided below the edge seal ES6 which is taken along a dotted line H-H′ in FIG. 40. The same configurations as those in FIGS. 31 to 33 are given the same reference signs, and duplicated descriptions thereon will be omitted.

In the edge seal region R_{ES}, as shown in FIG. 40, the edge seals ES1 to ES6 are provided in a ring shape so as to surround the periphery of the memory region R_{M} (not shown). Also, the wiring layers M1 is arranged so as to overlap with the edge seals ES1 to ES5 as viewed in the Z-direction.

The wiring layer M1 provided below the edge seal ES6 (in the −Z-direction) overlaps partially with the edge seal ES6 and meanders as viewed in the Z-direction as shown in FIGS. 40 and 41, for example. More specifically, for example, as shown in FIG. 41, the wiring layer M1 (the wiring m1d thereof) provided below the edge seal ES6 (in the −Z-direction) has a plurality of partial regions each having a predetermined angle with the edge seal ES6 as viewed in the Z-direction. These partial regions overlap partially with the edge seal ES6 as viewed in the Z-direction. The predetermined angle is set to about 15 degrees to 75 degrees, and is appropriately determined so as to enhance the coverage rate of the wiring layer M1 provided below the edge seal ES6 (in the −Z-direction) as viewed in the Z-direction.

For example, as shown in FIG. 42, the width in the Y-direction of the wiring m1d of the wiring layer M1 provided below the edge seal ES6 is larger than the width in the Y-direction of the edge seal ES6 as viewed in the Z-direction.

As described above, in Example 4, the wiring layer M1 below the edge seal ES6 can be provided so as to overlap partially with the edge seal ES6 and meander as viewed in the Z-direction. As a result, it is possible to enhance the coverage rate of the wiring layer M1 in the Z-direction of the edge seal ES6 even when the size in the Y-direction of the wiring layer M1 located below the edge seal ES6 cannot be increased as in the case of Examples 1 and 2, so that it is possible to reduce the difference in coverage rate of the wiring layer M1 between the edge seal region R_{ES} and the end portion of the kerf region R_{K} in the chip C_{M}.

Furthermore, in FIGS. 40 and 41, when the edge seal ES6 is viewed in the Z-direction, the wiring layer M1 is visible, but this Example is not limited to this configuration. The wiring layer M0 or the wiring layer V1 may also be visible. In this case, as viewed in the Z-direction, the wiring layer M0, the wiring layer V1, or the wiring layers M0 and V1 are arranged between the edge seal ES6 and the wiring layer M1 shown in FIG. 42, for example.

### Example 5

The first embodiment and Examples 1 to 4 have been described while applying the case where the floated wiring layer M1 provided below the edge seal ES6 is provided to be connected (continuous) as viewed in the Z-direction, but they are not limited to the above configuration. In the following Example 5 will be described while applying a case where the floated wiring layers M1 is discontinuously arranged as viewed in the Z-direction.

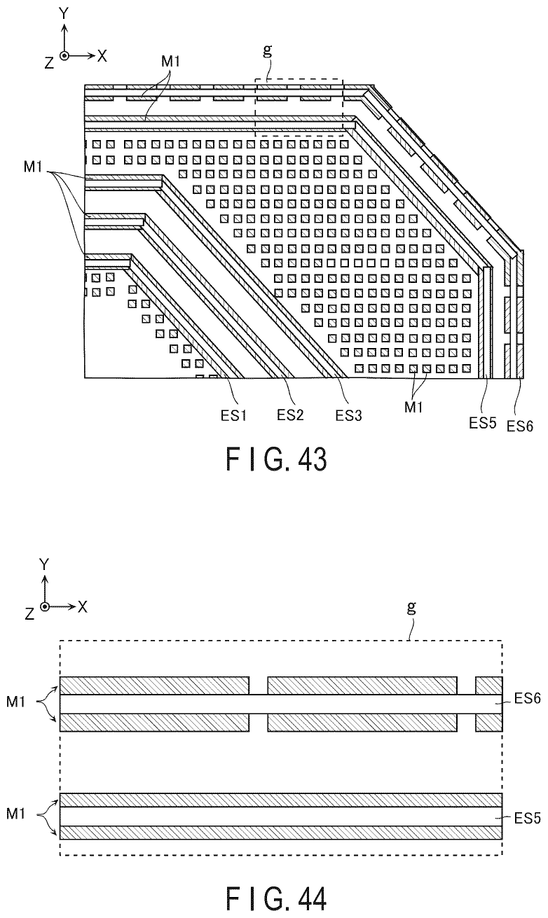

FIG. 43 is a plan view diagram schematically showing the arrangement of a plurality of edge seals ES1 to ES6 and the arrangement of wiring layers M1 in an edge seal region R_{ES} according to Example 5 of the first embodiment. FIG. 44 is a plan view diagram schematically showing an enlarged part of FIG. 43. The cross sectional view schematically showing the structure of the wiring layer M1 provided below the edge seal ES6 is the same as that in FIG. 36, so the description thereon will be omitted. Furthermore, the same configurations as those in FIGS. 31 and 32 are given the same reference signs, and duplicated descriptions thereon will be omitted.

In the edge seal region R_{ES}, as shown in FIG. 43, the edge seals ES1 to ES6 are provided in a ring shape so as to surround the periphery of a memory region R_{M} (not shown). Also, the wiring layers M1 are arranged so as to overlap with the edge seals ES1 to ES5 as viewed in the Z-direction.

For example, as shown in FIGS. 43 and 44, the wiring layer M1 provided below the edge seal ES6 (in the −Z-direction) has portions that partially overlap with the edge seal ES6 and are discontinuous as viewed in the Z-direction. More specifically, for example, as shown in FIG. 44, the wiring layer M1 provided below the edge seal ES6 (in the −Z-direction) is a single wiring consisting of a plurality of partial regions spaced apart from one another as viewed in the Z-direction. These partial regions at least partially overlap with the edge seal ES6 as viewed in the Z-direction. It is noted that the distance between adjacent partial regions in the X-direction (the distance between discontinuous portions) may be set to a predetermined percentage of the length of the partial region in the X-direction (the wiring length).

Furthermore, for example, as shown in FIG. 44, the width in the Y-direction of the wiring layer M1 provided below the edge seal ES6 is larger than the width in the Y-direction of the edge seal ES6 as viewed in the Z-direction.

In this way, in Example 5, the wiring layer M1 can be provided below the edge seal ES6 so as to have portions that partially overlap with the edge seal ES6 and are discontinuous as viewed in the Z-direction. As a result, it is possible to enhance the coverage rate of the wiring layer M1 in the Z-direction of the edge seal ES6 as compared with a case where the wiring layer M1 is not provided below the edge seal ES6, so that it is possible to reduce the difference in coverage rate of the wiring layer M1 between the edge seal region R_{ES} and the end portion of the kerf region R_{K} in the chip C_{M}.

Furthermore, since the wiring layer M1 below the edge seal ES6 is provided so as to have discontinuous portions, cracks or peeling which occurs from the kerf region R_{K} on the outer edge of the chip during the dicing step can be restrained from progressing along the entire wiring layer M1 below the edge seal ES6.

The wiring layer M1 provided below the edge seal ES6 is not limited to a single wiring consisting of a plurality of partial regions spaced apart from one another as viewed in the Z-direction, but may include a plurality of wirings as described in the third embodiment.

Furthermore, in FIGS. 43 and 44, the wiring layer M1 is visible when the edge seal ES6 is viewed in the Z-direction, but the Example 5 is not limited to this configuration. The wiring layer M0 or the wiring layer V1 may also be visible.

### Other Embodiments

The semiconductor storage devices according to the first embodiment and Examples 1 to 5 have been described above. However, the above semiconductor storage devices are merely examples, and the specific configurations, etc. can be adjusted as appropriate.

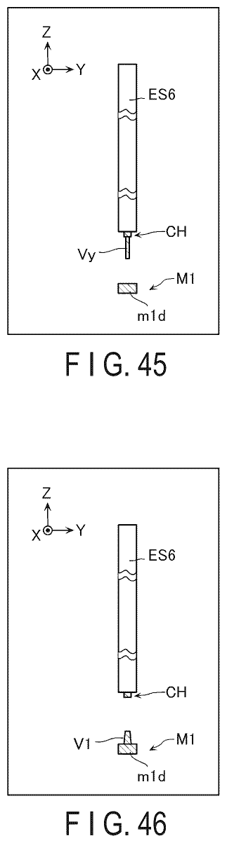

FIGS. 45 to 48 are cross sectional diagrams schematically showing the structures of an edge seal ES6 and a conductive layer below the edge seal ES6 according to other embodiments.

For example, it has been described that as shown in FIG. 10, the edge seal ES6 according to the first embodiment, etc. is connected to the wiring ch at a position where it overlaps with the wiring ch as viewed in the Z-direction, and the wiring m1 of the wiring layer M1 which is spaced apart from the edge seal ES6 and is not electrically connected to the edge seal ES6 is provided below the edge seal ES6. However, the first embodiment, etc. are not limited to the above configuration. The wiring m1d of the wiring layer M1 which is spaced apart from the edge seal ES6 may be provided without providing the wiring layer M0.

Specifically, for example, as shown in FIG. 45, the edge seal ES6 may be connected to the wiring ch at a position where it overlaps with the wiring ch as viewed in the Z-direction, the wiring ch may be connected to the wiring Vy, and the wiring m1d of the wiring layer M1 which is spaced apart from the edge seal ES6 and is not electrically connected to the edge seal ES6 may be provided below the edge seal ES6.

Furthermore, for example, as shown in FIG. 46, the edge seal ES6 may be connected to the wiring ch at a position where it overlaps with the wring ch as viewed in the Z-direction, and the wiring m1d of the wiring layer M1 that is spaced apart from the edge seal ES6 and is not electrically connected to the edge seal ES6 may be provided below the edge seal ES6, and the wiring m1d may be connected to the wiring V1.

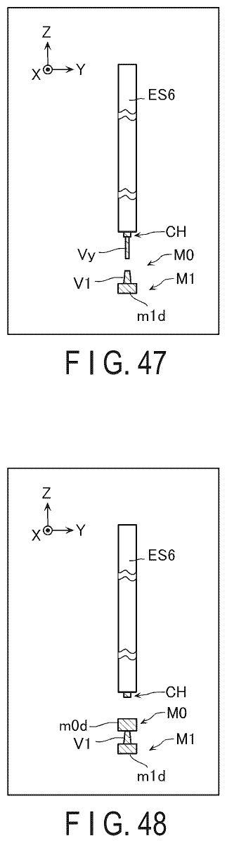

Furthermore, for example, as shown in FIG. 47, the edge seal ES6 may be connected to the wiring ch at a position where it overlaps with the wiring ch as viewed in the −Z-direction, the wiring ch may be connected to the wiring Vy, the wiring m1d of the wiring layer M1 that is spaced apart from the edge seal ES6 and is not electrically connected to the edge seal ES6 may be provided below the edge seal ES6, and the wiring m1d may be connected to the wiring V1.

Furthermore, the wiring m0d of the wiring layer M0 may be provided if the wiring m1d of the wiring layer M1 is spaced apart from the edge seal ES6 and is not electrically connected to the edge seal ES6. Specifically, for example, as shown in FIG. 48, the edge seal ES6 may be connected to the wiring ch at a position where it overlaps with the wiring ch as viewed in the Z-direction, the wiring m1d of the wiring layer M1 that is spaced apart from the edge seal ES6 and is not electrically connected to the edge seal ES6 may be provided below the edge seal ES6, the wiring m1d may be connected to the wiring V1, and the wiring V1 may be connected to the wiring m0d of the wiring layer M0. The wiring m0d of the wiring layer M0 is provided at a position where it overlaps with the wiring ch as viewed in the Z-direction, but the wiring m0d of the wiring layer M0 is spaced apart from the wiring ch and is not electrically connected to the wiring ch.

Next, a structure in which the wiring m1d of the wiring layer M1 arranged below the edge seal ES6 may be electrically connected to the edge seal ES6 will be described. In this case, the wiring layer M0 can be arranged so as to overlap with the wiring layer M1 as viewed in the Z-direction.

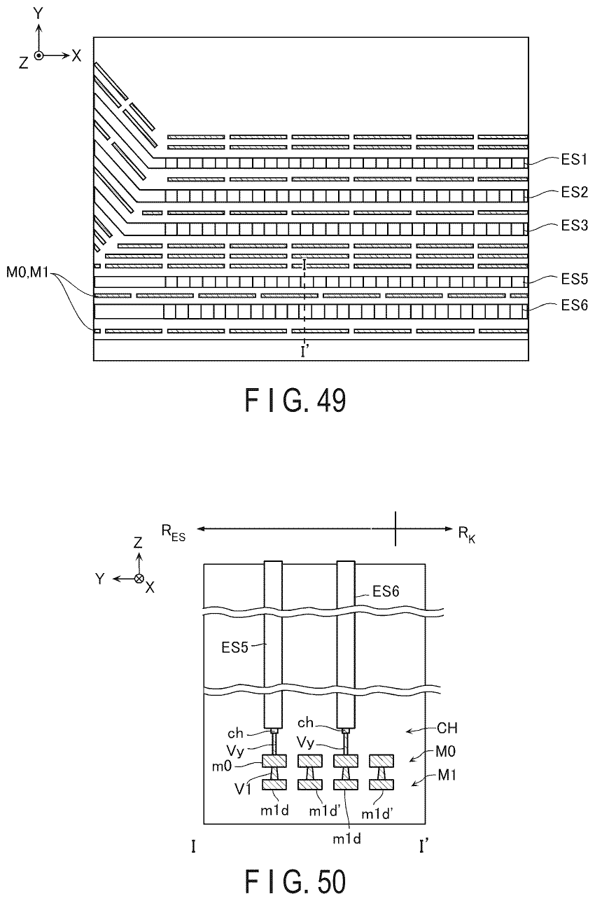

FIG. 49 is a plan view diagram schematically showing the arrangement of the edge seals ES1 to ES6 and the arrangement of the wiring layers M0 and M1 in the edge seal region R_{ES} according to other embodiments. FIG. 50 is a cross sectional diagram schematically showing the structure of the wiring layers M0 and M1 arranged below the edge seal ES6 which is taken along a dotted line I-I′ in FIG. 49.

In the edge seal region R_{ES}, as shown in FIG. 49, the edge seals ES1 to ES6 are arranged in a ring shape so as to surround the periphery of the memory region R_{M} (not shown). Furthermore, the wiring layers M0 and M1 may be arranged at positions where they overlap with the edge seals ES1 to ES5 and positions where they do not overlap with the edge seals ES1 to ES5 as viewed in the Z-direction.

For example, as shown in FIG. 50, the wiring layer M1 provided below the edge seal ES6 (in the −Z-direction) may be arranged at a position where it partially overlaps with the edge seal ES6 and at a position where it does not overlap with the edge seal ES6 as viewed in the Z-direction.

Specifically, the wiring m1d of the wiring layer M1 may be arranged at a position where it partially overlaps with the edge seal ES6, and the wiring m1d′ of the wiring layer M1 may be arranged at a position where it does not overlap with the edge seal ES6. These wirings m1d and m1d′ are spaced apart from each other.

As viewed in the Z-direction, the wiring m0d of the wiring layer M0 may be provided so as to overlap with the wiring m1d of the wiring layer M1 arranged at a position where the wiring m1d of the wiring layer M1 partially overlaps with the edge seal ES6, and the wiring m1d and the wiring m0d may be electrically connected to each other. Likewise, as viewed in the Z-direction, the wiring m0d of the wiring layer M0 may be provided so as to overlap with the wiring m1d′ of the wiring layer M1 arranged at a position where the wiring m1d′ of the wiring layer M1 does not overlap with the edge seal ES6, and the wiring m1d′ and the wiring m0d may be electrically connected to each other via the wiring V1.

In such a case, for example, as shown in FIG. 50, the edge seal ES6 is electrically connected to the wirings ch, Vy, m0d, V1, and m1d at positions where the edge seal ES6 overlaps with these wirings as viewed in the Z-direction, and the edge seal ES6 is not electrically connected to the wirings m0d, V1, and m1d at positions where the edge seal ES6 does not overlap with these wirings as viewed in the Z-direction.

For example, as shown in FIG. 49, each of the wiring layers M0 and M1 that is provided at an overlapping position with the edge seal ES6 and a non-overlapping position with the edge seal ES6 below the edge seal ES6 (in the −Z-direction) is a single wiring consisting of a plurality of partial regions spaced apart from one another as viewed in the Z-direction.

In this way, the edge seal ES6 is provided on the outermost peripheral side of the edge seals ES1 to ES6 in the edge seal region R_{ES}. However, as described above, the wiring layers M0 and M1 are provided at a non-overlapping position with the edge seal ES6 below the edge seal ES6 and on the outer peripheral side beyond the edge seal ES6 so as not to be electrically connected to the edge seal ES6, and the wirings ch and Vy are omitted, whereby it is unnecessary to omit the wirings ch and m0 in the wiring layers CH and M0 below the edge seal ES6.

In the above description, below the edge seal ES6 (in the −Z-direction), the wiring layer M1 is provided at a non-overlapping position with the edge seal ES6, and the wiring layer M0 is provided at an overlapping position with the edge seal ES6 in the Z-direction. However, the embodiments are not limited to this configuration, and the wiring layer M0 may not be provided.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor storage device comprising:
a first chip and a second chip bonded together via a plurality of bonding electrodes, wherein
the second chip has a memory region including a memory cell array and an edge seal region surrounding the memory region,
the first chip includes a semiconductor substrate,
the second chip includes:
a plurality of edge seals, each extending in the edge seal region in a first direction intersecting a surface of the semiconductor substrate and surrounding the memory region as viewed in the first direction, the plurality of edge seals including two or more inner edge seals and an outermost edge seal that is an outermost one of the plurality of edge seals;
a first wiring layer provided at a first layer level on a first chip side of the plurality of edge seals; and
a second wiring layer that is provided at a second layer level on a first chip side of the first wiring layer and contains tungsten (W),
the first wiring layer includes a plurality of first wirings that are provided in the edge seal region at positions overlapping with the inner edge seals, respectively, but not with the outermost edge seal, as viewed in the first direction and electrically connected to the inner edge seals, respectively, and
the second wiring layer includes:
a plurality of second wirings that are provided in the edge seal region at positions overlapping with the inner edge seals, respectively, but not with the outermost edge seal, as viewed in the first direction and electrically connected to the inner edge seals, respectively; and
a third wiring that is provided in the edge seal region on an outer side of the second wirings as viewed in the first direction, and electrically separated and spaced apart from the outermost edge seal.

2. The semiconductor storage device according to claim 1, wherein
one of the inner edge seals is electrically connected to one of the plurality of bonding electrodes via one of the first wirings and one of the second wirings, and
another one of the inner edge seals is electrically separated from each of the plurality of bonding electrodes.

3. The semiconductor storage device according to claim 1, wherein the third wiring includes a portion that overlaps with the outermost edge seal as viewed in the first direction.

4. The semiconductor storage device according to claim 1, wherein the third wiring includes a portion that does not overlap with the outermost edge seal as viewed in the first direction.

5. The semiconductor storage device according to claim 1, wherein
the outermost edge seal has a first width in a second direction intersecting the first direction in a cross section, and
the third wiring has a second width in the second direction in the cross section, the second width being greater than the first width.

6. The semiconductor storage device according to claim 1, wherein
the second wiring layer further includes a fourth wiring that is provided in the edge seal region on an outer side of the third wiring as viewed in the first direction, and electrically separated and spaced apart from the outermost edge seal, and
the third wiring is provided on an inner side than outermost edge seal as viewed in the first direction.

7. The semiconductor storage device according to claim 6, wherein the third wiring and the fourth wiring do not overlap with the outermost edge seal as viewed in the first direction.

8. The semiconductor storage device according to claim 1, wherein the third wiring partially overlaps with the outermost edge seal and meanders as viewed in the first direction.

9. The semiconductor storage device according to claim 8, wherein
the third wiring has a plurality of subregions each having a predetermined angle with the outermost edge seal as viewed in the first direction, and
the plurality of subregions partially overlap with the outermost edge seal as viewed in the first direction.

10. The semiconductor storage device according to claim 8, wherein the third wiring has a plurality of subregions spaced apart from one another as viewed in the first direction, and the plurality of subregions overlap at least partially with the outermost edge seal as viewed in the first direction.

11. The semiconductor storage device according to claim 1, wherein the number of the inner edge seals is at least four.

12. A semiconductor storage device comprising:
a first chip and a second chip bonded together via a plurality of bonding electrodes, wherein
the second chip has a memory region including a memory cell array and an edge seal region surrounding the memory region,
the first chip includes a semiconductor substrate, the second chip includes:
a plurality of edge seals, each extending in the edge seal region in a first direction intersection a surface of the semiconductor substrate and surrounding the memory region as viewed in the first direction;
a first wiring layer provided at a first layer level on a first chip side of the plurality of edge seals; and
a second wiring layer that is provided at a second layer level on a first chip side of the first wiring layer and contains tungsten (W),
the first wiring layer includes a plurality of first wirings that are provided in the edge seal region at positions overlapping with the plurality of edge seals, respectively, as viewed in the first direction and electrically connected to the plurality of edge seals, respectively, and
the second wiring layer includes:
a plurality of second wirings that are provided in the edge seal region at positions overlapping with the plurality of edge seals, respectively, as viewed in the first direction, and electrically connected to the plurality of edge seals, respectively;
a third wiring that is provided in the edge seal region on an inner side of an outermost one of the second wirings as viewed in the first direction, and electrically separated and spaced apart from any of the plurality of edge seals; and
a fourth wiring that is provided in the edge seal region on an outer side of the outermost one of the second wirings as viewed in the first direction, and electrically separated and spaced apart from any of the plurality of edge seals.

13. The semiconductor storage device according to claim 11, wherein the third wiring is provided between an outermost one of the second wirings and a next outer one of the second wirings.

14. The semiconductor storage device according to claim 11, wherein the third wiring does not overlap with any of the plurality of edge seals as viewed in the first direction.

15. The semiconductor storage device according to claim 11, wherein the fourth wiring does not overlap with any of the plurality of edge seals as viewed in the first direction.

16. The semiconductor storage device according to claim 11, wherein the first wiring layer further includes:
a fifth wiring that is provided in the edge seal region on an inner side of an outermost one of the first wirings as viewed in the first direction, and electrically connected to the third wiring; and
a sixth wiring that is provided in the edge seal region on an outer side of an outermost one of the first wirings as viewed in the first direction, and electrically connected to the fourth wiring.

17. The semiconductor storage device according to claim 16, wherein the fifth wiring does not overlap with any of the plurality of edge seals as viewed in the first direction.

18. The semiconductor storage device according to claim 16, wherein the sixth wiring does not overlap with any of the plurality of edge seals as viewed in the first direction.

19. The semiconductor storage device according to claim 11, wherein
one of the plurality of edge seals is electrically connected to one of the plurality of bonding electrodes via one of the first wirings and one of the second wirings, and
another one of the plurality of edge seals is electrically separated from each of the plurality of bonding electrodes.

20. The semiconductor storage device according to claim 1, wherein the number of the plurality of edge seals is at least five.
